(19) United States
(12) Patent Application Publication
(10) Pub. No.: US 2008/0191211 A1
(43) Pub. Date: Aug. 14, 2008

(54) THIN FILM TRANSISTOR ARRAY SUBSTRATE, METHOD OF MANUFACTURING THE SAME, AND DISPLAY DEVICE

(75) Inventors: Shinichi Yano, Kumamoto (JP); Kazunori Inoue, Tokyo (JP); Nobuaki Ishiga, Kumamoto (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 12/029,958

(22) Filed: Feb. 12, 2008

(30) Foreign Application Priority Data
Feb. 13, 2007 (JP) 2007-031929
Jul. 24, 2007 (JP) 2007-192482

(51) Int. Cl. H01L 29/04; H01L 21/02

(52) U.S. Cl. 257/59; 438/30; 257/E21.002; 257/E29.003

(57) ABSTRACT

A thin film transistor array substrate includes a gate electrode formed on a substrate, a gate insulating film formed over the gate electrode, a source electrode and a drain electrode that are formed on the gate insulating film and include a transparent conductive film and a metal film formed on the transparent conductive film, a semiconductor film formed over the source electrode and the drain electrode to be electrically connected to the source electrode and the drain electrode, and a pixel electrode formed extending from the drain electrode.

### BACKGROUND OF THE INVENTION

1. Field of the Invention

The present invention relates to a thin film transistor array substrate, a method of manufacturing the thin film transistor array substrate, and a display device.

2. Description of Related Art

Display devices using liquid crystal, which are of a type among flat panel displays replacing CRTs, are being actively applied to products utilized their characteristics of being low in power consumption and thin.

Liquid crystal displays (hereinafter referred to as LCDs) include a simple matrix LCD and a TFT-LCD using thin film transistors (hereinafter referred to as TFTs) as switching elements. The TFT-LCD is superior in portability and quality of display to the CRT and the simple matrix LCD and widely used in laptop personal computers and the like. In general, in the TFT-LCD, a liquid crystal layer is interposed between a TFT array substrate on which TFTs are formed in an array arrangement and an opposing substrate, and a polarizing plate is provided on the exterior side of each of the TFT array substrate and the opposing substrate. Further, a light source is provided on one side of these. With such a configuration, the TFT-LCD makes a good display.

In order to produce the TFT array substrate for use in such a TFT-LCD, TFTs need to be formed in an array arrangement on a glass substrate by use of semiconductor technology, which needs many processes. Hence, various defects and failures are likely to occur, resulting in low yield. Further, there is the problem that the number of manufacturing equipments necessary in production is large, resulting in higher production costs.

One of methods of manufacturing TFT array substrates that have been conventionally used is to use five photolithography processes (hereinafter called a five-mask process) as described in, e.g., Japanese Unexamined Patent Application Publication No. 08-50308. In this reference and Japanese Unexamined Patent Application Publication No. 2001-244467, there are disclosed a manufacturing method using the five-mask process and the configuration of a TFT array substrate manufactured according to the method.

Meanwhile, in Japanese Unexamined Patent Application Publication No. 2005-283689, there is disclosed a method of manufacturing TFT array substrates using four photolithography processes (hereinafter called a four-mask process). In this reference, the four-mask process is realized by consolidating the second and the third photolithography processes of the above Publication No. 08-50308 into one photolithography process. That is, by partially changing the thickness of a photo-resist film by use of a halftone exposure technique, semiconductor layers, source/drain electrodes, and channel regions of TFTs are formed with use of one photolithography process.

In the four-mask process, resist patterns different in thickness are formed using the halftone exposure technique. A resist pattern of thicker film thickness is formed on the regions where semiconductor layers and source/drain electrodes are to be formed, and a resist pattern of thinner film thickness is formed on the regions where channel regions are to be formed. However, it is very difficult to control the size of the resist pattern of thinner film thickness, which varies depending on various parameters. Hence, with the four-mask process, it is very difficult to control the width of a semiconductor layer that is the distance between a source electrode and a drain electrode, i.e., a channel length.

It is necessary to accurately control all parameters such as resist film thickness uniformity and resist film quality uniformity before exposure, an optimum halftone exposure amount, uniformity of resist development characteristics, and uniformity in reducing the resist film thickness. In particular, a photolithography technique that forms a resist remaining thin as the resist pattern of thinner film thickness and a process technique that uniformly reduces the resist film in thickness are very difficult to control at present. Since a large number of TFTs different in channel length exist in a panel, with the conventional four-mask process, the characteristics of the TFTs different in channel length vary, resulting in the occurrence of display unevenness or point defects, thus lowering display quality and yield.

The present invention was made to solve the above problem, and an object thereof is to provide a thin film transistor array substrate, a method of manufacturing the same, and a display device which can facilitate the control of the channel lengths of TFTs without increasing the number of photolithography processes.

### SUMMARY OF THE INVENTION

According to an embodiment of the present invention, there is provided a thin film transistor array substrate that includes a gate electrode formed on a substrate, a gate insulating film formed over the gate electrode, a source electrode and a drain electrode that are formed on the gate insulating film and include a transparent conductive film and a metal film formed on the transparent conductive film, a semiconductor film formed over the source electrode and the drain electrode to be electrically connected to the source electrode and the drain electrode, and a pixel electrode formed extending from the drain electrode.

The present invention enables to provide a thin film transistor array substrate, a method of manufacturing the same, and a display device which can facilitate the control of the channel lengths of TFTs without increasing the number of photolithography processes.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 shows the structure of a TFT array substrate of a liquid crystal display according to the present invention;

FIG. 2 is a plan view of a TFT array substrate according to an embodiment 1;

FIG. 3 shows a cross-sectional structure of the TFT array substrate according to the embodiment 1 and is a sectional view on line III-III of FIG. 2;

FIG. 4 is a flow chart showing the flow of a manufacturing process for the TFT array substrate according to the embodiment 1;

FIGS. 5A to 5E are sectional views showing the manufacturing process for the TFT array substrate according to the embodiment 1;

FIGS. 6F to 6J are sectional views showing the manufacturing process for the TFT array substrate according to the embodiment 1;

FIG. 7 shows a cross-sectional structure of a TFT array substrate according to an embodiment 2;

FIG. 8 is a plan view of a TFT array substrate according to an embodiment 3;

FIG. 9 shows a cross-sectional structure of the TFT array substrate according to the embodiment 3 and is a sectional view on line IX-IX of FIG. 8;

FIG. 10 shows a cross-sectional structure of a TFT array substrate according to another example of the embodiment 3;

FIG. 11 is a plan view of a TFT array substrate according to an embodiment 4;

FIG. 12 shows a cross-sectional structure of the TFT array substrate according to the embodiment 4 and is a sectional view on line XII-XII of FIG. 11;

FIG. 13 shows a cross-sectional structure of a TFT array substrate according to another example of the embodiment 4;

FIG. 14 shows a cross-sectional structure of a TFT array substrate according to an embodiment 5;

FIG. 15 shows a cross-sectional structure of a TFT array substrate according to an embodiment 6;

FIG. 16 is a plan view of a TFT array substrate according to an embodiment 7;

FIG. 17 shows a cross-sectional structure of the TFT array substrate according to the embodiment 7 and is a sectional view on line XVII-XVII of FIG. 16;

FIGS. 18A to 18E are sectional views showing the manufacturing process for the TFT array substrate according to the embodiment 7;

FIGS. 19F to 19I are sectional views showing the manufacturing process for the TFT array substrate according to the embodiment 7;

FIGS. 20J to 20M are sectional views showing the manufacturing process for the TFT array substrate according to the embodiment 7;

FIG. 21 shows a cross-sectional structure of a TFT array substrate according to another example of the embodiment 7;

FIG. 22 is a plan view of a TFT array substrate according to yet another example of the embodiment 7; and

FIG. 23 is a sectional view on line XXIII-XXIII of FIG. 22.

### DESCRIPTION OF THE PREFERRED EMBODIMENTS

### Embodiment 1

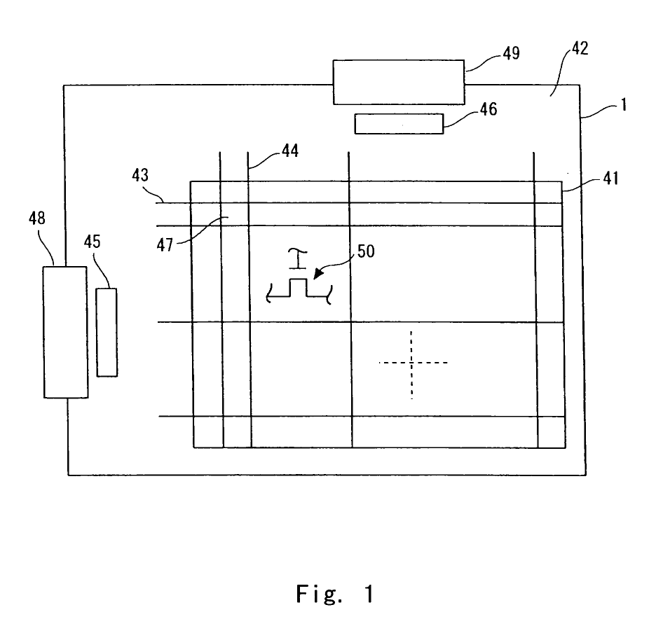

Firstly, a display device according to the present invention is explained with reference to FIG. 1. FIG. 1 is a front view showing the structure of an TFT array substrate used for a liquid crystal display. Although the display device according to the present invention is explained with a liquid crystal display as an example, it is only illustrative and a flat panel display or the like such as an organic EL display may be used. The overall structure of this liquid crystal display is common to the first to the seventh embodiments described below.

The liquid crystal display device according to the present invention includes an insulating substrate 1. The insulating substrate 1 is for example an array substrate such as a TFT array substrate. A display area 41 and a frame area 42 surrounding the display area 41 are provided to the insulating substrate 1. A plurality of gate lines (scanning signal lines) 43 and a plurality of source lines (display signal lines) 44 are formed in the display area 41. The plurality of gate lines 43 are provided in parallel. Likewise, the plurality of source lines 44 are provided in parallel. The gate lines 43 and source lines 44 are formed to cross each other. The gate lines 43 and signal lines 44 are orthogonal. Moreover, an area surrounded by adjacent gate lines 43 and source lines 44 is a pixel 47. Accordingly in the insulating substrate 1, pixels 47 are arranged in matrix.

Additionally in the frame area 42 of the insulating substrate 1, a scanning signal driving circuit 45 and a display signal driving circuit 46 are provided. The gate lines 43 are extended from the display area 41 to the frame area 42. Furthermore, the gate lines 43 are connected with the scanning signal driving circuit 45 at the end part of the insulating substrate 1. The source lines 44 are also extended from the display area 41 to the frame area 42. The source lines 44 are connected with the display signal driving circuit 46 at the end part of the insulating substrate 1. An external line 48 is connected near the scanning signal driving circuit 45. Furthermore, an external line 49 is connected near the display signal driving circuit 46. The external lines 48 and 49 are wiring boards such as FPC (Flexible Printed Circuit).

Various signals are supplied to the scanning signal driving circuit 45 and the display signal driving circuit 46 via the external lines 48 and 49. The scanning signal driving circuit 45 supplies a gate signal (scanning signal) to the gate line 43 according to an external control signal. By the gate signal, the gate lines 43 are selected sequentially. The display signal driving circuit 46 supplies a display signal to the signal lines 44 according to an external control signal or display data. This enables to supply a display voltage according to the display data to each of the pixels 47. Note that the scanning signal driving circuit 45 and the display signal driving circuit 46 are not limited to the structure disposed over the insulating substrate 1. For example, the driving circuits may be connected by TCP (Tape Carrier Package).

Inside the pixel 47, at least one TFT 50 is formed. The TFT 50 is placed near the intersection of the source line 44 and the gate line 43. For example, this TFT 50 supplies the display voltage to a pixel electrode. That is, by the gate signal from the gate line 43, the TFT 50, which is a switching device, is turned on. This enables to apply the display voltage to the pixel electrode connected to a drain electrode of the TFT 50 from the signal line 44. Moreover, an electric field according to the display voltage is generated between the pixel electrode and an opposing electrode. Note that an alignment layer (not shown) is formed over the surface of the insulating substrate 1.

Furthermore, an opposing substrate (not shown) is placed opposite to the insulating substrate 1. The opposing substrate is for example a color filter substrate and placed to the visible side. Over the opposing substrate, a color filter, black matrix (BM), an opposing electrode and an alignment layer and so on are formed. Note that the opposing electrode may be placed to the insulating substrate 1 side. In addition, a liquid crystal layer is held between the insulating substrate 1 and the opposing substrate. More specifically, liquid crystal is filled between the insulating substrate 1 and the opposing substrate. Further, a polarizing plate and retardation film or the like are provided to the outside surface the insulating substrate 1 and the opposing substrate. Moreover, a backlight unit or the like is provided to the non-visible side of a liquid crystal display panel.

The liquid crystal is driven by the electric field between the pixel electrode and the opposing electrode. That is, an alignment direction of the liquid crystal between the substrates changes. This changes the polarization state of the light passing through the liquid crystal layer. To be more specific, the light that has passed the polarizing plate and became a linearly polarized light changes its polarization state by the liquid crystal layer. More specifically, the light from the backlight unit becomes a linearly polarized light by the polarizing plate provided to the array substrate side. Further, by the linearly polarized light passing through the liquid crystal layer, the polarization state changes.

Accordingly, the amount of light passing through the polarizing plate of the opposing substrate side varies according to the polarization state. More specifically, among transmitted light transmitting from the backlight unit through the liquid crystal panel, the amount of light passing through the polarizing plate of the visible side varies. The alignment direction of the liquid crystal varies according to the applied display voltage. Therefore, by controlling the display voltage, the amount of light passing through the polarizing plate of the visible side can be changed. That is, by varying the display voltage by each pixel, a desired image can be displayed.

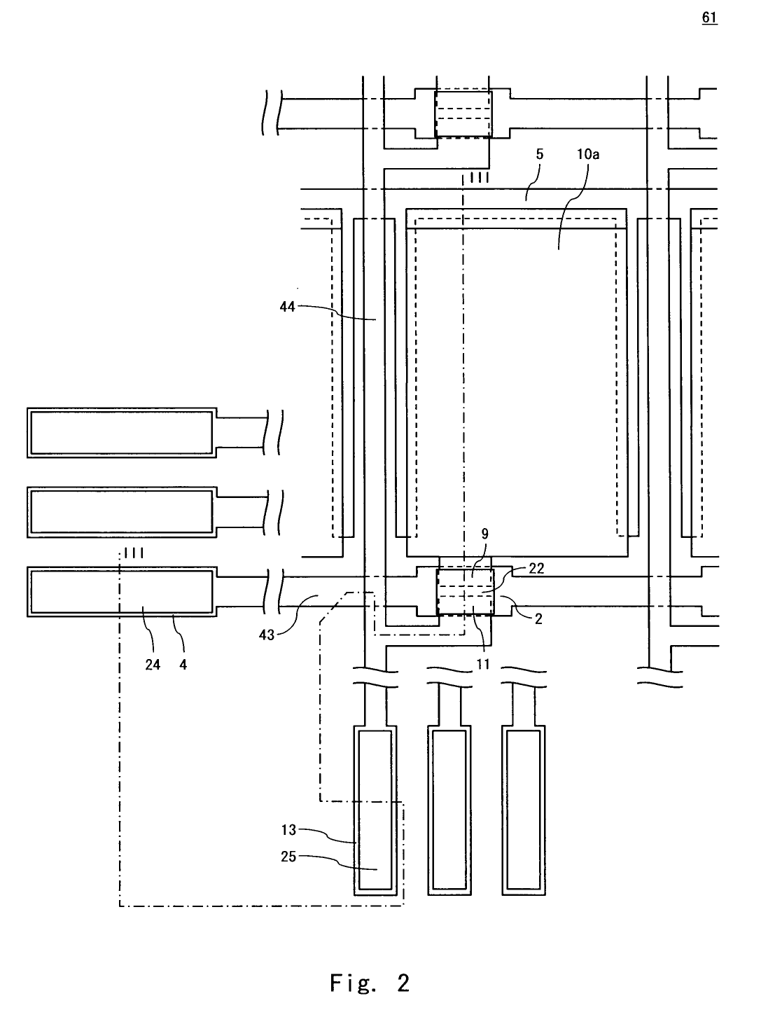

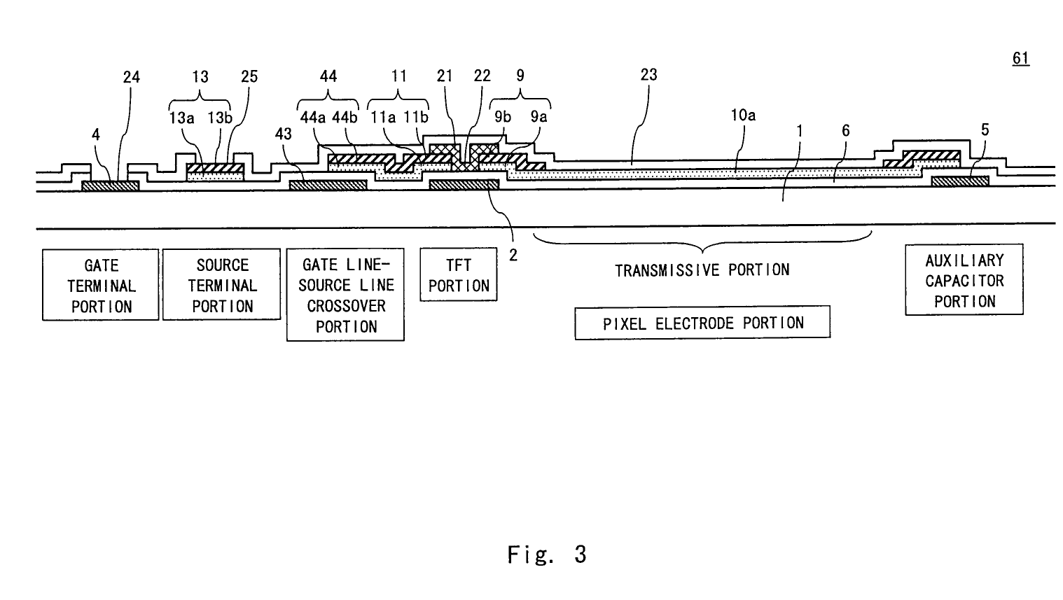

Next, the configuration of a TFT array substrate will be described using FIGS. 2 and 3. FIG. 2 is a plan view of a TFT array substrate 61 according to the present embodiment 1, and FIG. 3 is a sectional view on line III-III of FIG. 2. In FIG. 2, only contact holes are shown as to a gate insulating film 6 and a passivation film 23. In FIGS. 2 and 3, a gate electrode 2, a gate line 43, a gate terminal 4, and an auxiliary capacitor electrode 5 are formed by a first electrode film on an insulating substrate 1. The insulating substrate 1 is a transparent insulating substrate made of glass, plastic, or the like. The gate line 43 is connected to the gate electrode 2 at the outside of the TFT portion and also connected to the gate terminal 4 in a frame area 42. A video gate signal is input to the gate line 43 through the gate terminal 4. A gate insulating film 6 is formed by a first insulating film so as to cover these gate electrode 2, gate line 43, gate terminal 4, and auxiliary capacitor electrode 5.

Provided on the gate insulating film 6 are a drain electrode 9, a transmissive pixel electrode 10a, a source electrode 11, a source line 44, and a source terminal 13. The drain electrode 9, source electrode 11, source line 44, and source terminal 13 are formed by a second electrode film. The second electrode film is a stacked film having a transparent conductive film on its lower side and a metal film on its upper side. The drain electrode 9 comprises a drain electrode 9a of the transparent conductive film and a drain electrode 9b of the metal film. Likewise, the source electrode 11 comprises a source electrode 11a of the transparent conductive film and a source electrode 11b of the metal film. The source line 44 is formed of a source line 44a and a source line 44b laid one on top of the other and connected to the source electrode 11. The source line 44 is connected to the source terminal 13 in the frame area 42. A video source signal is input to the source line 44 through the source terminal 13. The source terminal 13 comprises a source terminal 13a and a source terminal 13b. The source line 44a and the source terminal 13a are formed by the transparent conductive film, and the source line 44b and the source terminal 13b are formed by the metal film. The transmissive pixel electrode 10a is formed by the transparent conductive film that extends from the drain electrode 9a. The metal film is not formed on the transmissive pixel electrode 10a.

In the present embodiment, a semiconductor film 21 is formed over the drain electrode 9 and the source electrode 11, differing from the Japanese Unexamined Patent Application Publications No. 08-50308 and No. 2005-283689. To be specific, the semiconductor film 21 of substantially the same size as the gate electrode 2 is formed over the drain electrode 9b and the source electrode 11b, and part of the semiconductor film 21 that is between the drain electrode 9 and the source electrode 11 forms a channel region 22. Further, the semiconductor film 21 is electrically connected to the drain electrode 9 and the source electrode 11 at the upper surfaces of the drain electrode 9b and the source electrode 11b respectively. In the present embodiment, the semiconductor film 21 is formed over the drain electrode 9 and the source electrode 11.

Over the semiconductor film 21 provided in this way, a passivation film 23 is formed by a second insulating film and protects the above-mentioned electrodes, line pattern, and the like. A gate terminal opening 24 as a contact hole is formed on the gate terminal 4 by partially removing the gate insulating film 6 and the passivation film 23. A source terminal opening 25 as a contact hole is formed on the source terminal 13 by partially removing the passivation film 23.

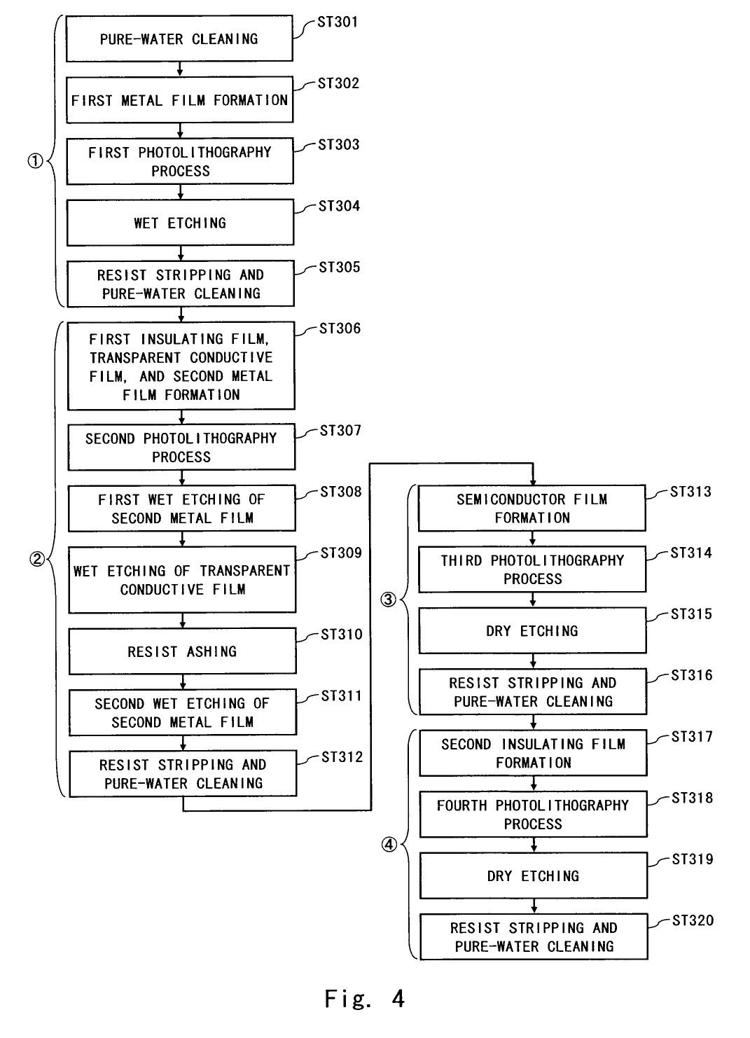

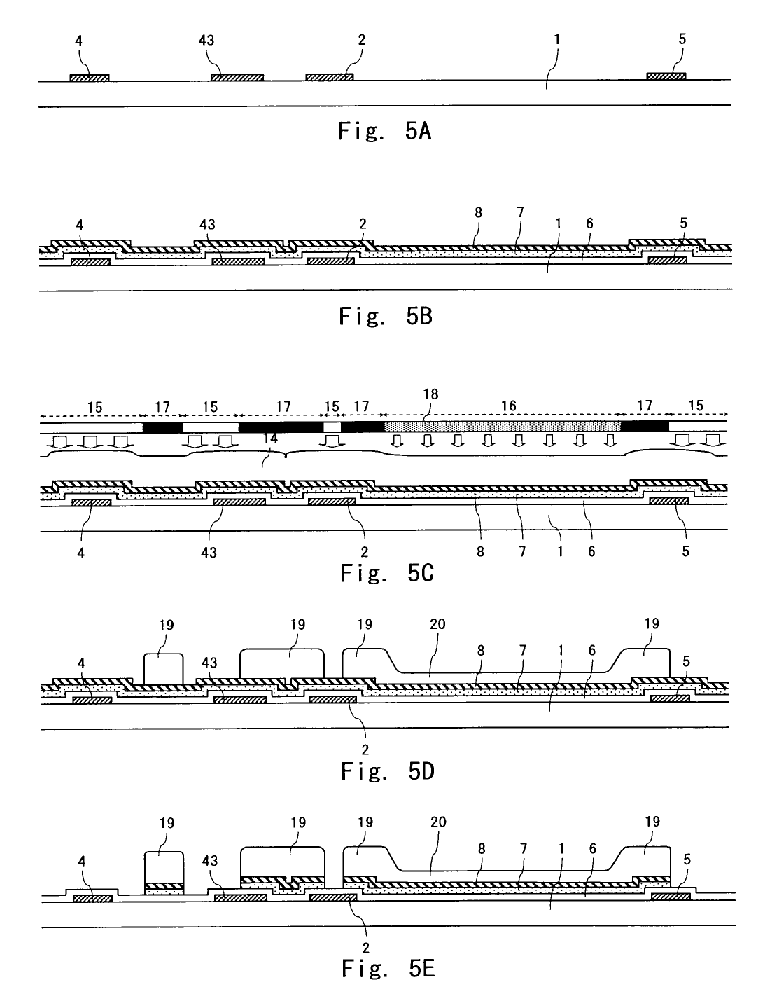

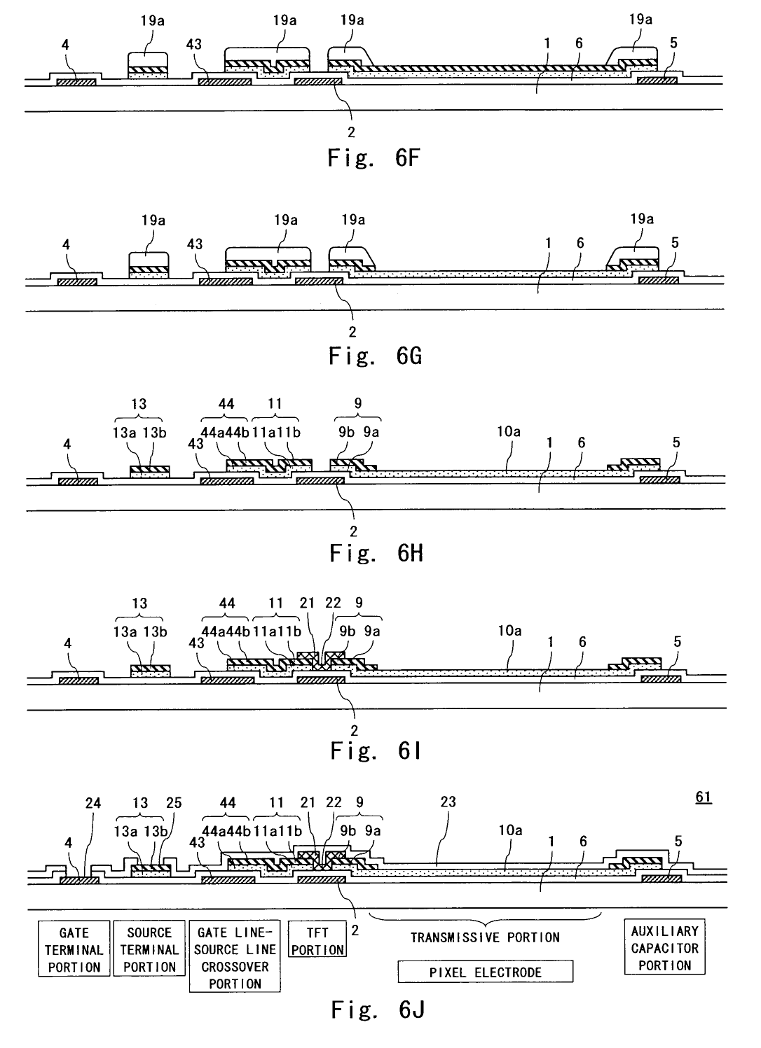

Next, the method of manufacturing the TFT array substrate 61 of the present embodiment 1 will be described in detail using FIGS. 4, 5A to 5E, and 6F to 6J. FIG. 4 is a flow chart showing the flow of a manufacturing process for the TFT array substrate 61 according to the present embodiment 1. Here, description will be made with reference to FIGS. 5A to 5E and FIGS. 6F to 6J as needed. FIGS. 5A to 5E and FIGS. 6F to 6J are sectional views showing the manufacturing process for the TFT array substrate 61 according to the present embodiment 1.

First, an insulating substrate 1 such as a glass substrate is cleaned with pure water (ST301). Instead of pure water, hot sulfuric acid can be used for cleaning. After the cleaning, a first metal film as the first electrode film is formed on the insulating substrate 1 (ST302). One of Al, Mo, Cr, and alloys consisting primarily of them, which are low in resistivity, is preferably used as the first metal film. Here, a Cr film of 200 nm in thickness is formed by use of a known DC magnetron sputtering method using Ar gas. Next, a first photolithography process is performed (ST303), thereby forming a resist pattern on the first metal film. Then, wet etching is performed (ST304), thereby patterning the first metal film. The Cr film is etched with use of, for example, a known etchant containing cerium diammonium nitrate and perchloric acid. Thereafter, the resist pattern is removed by stripping off, and the whole is cleaned with pure water (ST305). By this means, the gate electrode 2, the gate line 43, the gate terminal 4, and the auxiliary capacitor electrode 5 are formed as shown in FIG. 5A.

Next, a first insulating film, a transparent conductive film, and a second metal film are formed (ST306). To be specific, as shown in FIG. 5B, a gate insulating film 6 as the first insulating film is formed so as to cover the gate electrode 2, the gate line 43, the gate terminal 4, and the auxiliary capacitor electrode 5. In the present embodiment, a silicon nitride film (SiN film) of 400 nm in thickness is formed as the gate insulating film 6 with use of a chemical vapor deposition (CVD) method. Then, the transparent conductive film 7 is formed on the gate insulating film 6 and further the second metal film 8 is formed thereon, so as to form a second electrode film. For example, an ITO film of a mixture of indium oxide (In₂O₃) and tin oxide (SnO₂) can be used as the transparent conductive film 7. Here, the ITO film of 100 nm in thickness is formed by use of a sputtering method using Ar gas, and a Cr film of 200 nm in thickness is formed as the second metal film 8 by use of the DC magnetron sputtering method using Ar gas.

Thereafter, a second photolithography process is performed (ST307). First, an about 1.6 μm thick photoresist 14 is coated with use of a spin coater and prebaked at 120° C. for about 90 sec. Then, as shown in FIG. 5C, the photoresist 14 is exposed to light. At this time, multiphase exposure (multi-tone exposure) is performed using a photomask 18 having first exposure portions 15, second exposure portions 16, and shielding portions 17.

The first exposure portion 15 has such a characteristic that a necessary exposure amount of light to fully expose the photoresist 14 is transmitted. Meanwhile, the second exposure portion 16 has such a characteristic that light of an exposure amount equal to about 20 to 40% of that of the first exposure portion 15 is transmitted. The shielding portion 17 shields the photoresist 14 from exposure to light. The photomask 18 is a halftone mask, a gray tone mask, or the like. In the halftone mask, a filter film to reduce the transmission amount of light of a wavelength in the range of, usually, 350 to 450 nm is formed on the second exposure portion 16. In the gray tone mask, a pattern of slits narrower than resolution for reducing the exposure amount using optical diffraction is provided on the second exposure portion 16.

After the exposure using the photomask 18, the photoresist 14 is developed with an organic alkaline-based developer, and then postbaked at 120° C. for about 180 sec, and thereby resist patterns 19 and 20 different in thickness are formed simultaneously as shown in FIG. 5D. The thicker resist pattern 19 is formed on the regions where a drain electrode 9 and a source electrode 11, a source terminal 13, and a source line 44 are to be provided, and the thinner resist pattern 20 is formed on the region where a transmissive pixel electrode 10a is to be provided. Thus, the resist pattern having the thicker film thickness and thinner film thickness portions is formed.

For example, a novolac resin-based positive resist is used as the photoresist 14. In the photomask 18, the shielding portions 17 are provided corresponding to the regions where the drain electrode 9 and the source electrode 11, the source terminal 13, and the source line 44 are to be formed, and the second exposure portion 16 is provided corresponding to the region where the transmissive pixel electrode 10a is to be formed. When the photoresist 14 is exposed to light with this photomask 18 and developed, part of the photoresist 14 corresponding to the first exposure portion 15 is removed so that the second metal film 8 is exposed partially. The thicker resist pattern 19 is formed corresponding to the shielding portions 17, and the thinner resist pattern 20 is formed corresponding to the second exposure portions 16. Preferably, the thickness of the resist pattern 19 is about 1.4 to 1.6 μm, and the thickness of the resist pattern 20 is about 0.4 μm.

Thereafter, the second metal film 8 is wet etched for the first time with the masking resist patterns 19, 20 (ST308). For example, the second metal film 8, that is, the Cr film is partially removed with use of the known etchant containing cerium diammonium nitrate and perchloric acid. Further, the transparent conductive film 7 is wet etched with the masking resist patterns 19, 20 (ST309). The transparent conductive film 7 is partially removed with use of a known solution containing hydrochloric acid and nitric acid. By this means, the configuration as shown in FIG. 5E is obtained. Parts of the transparent conductive film 7 and the second metal film 8 corresponding to the first exposure portions 15 have been removed by the etching.

Subsequently, resist ashing is performed with use of oxygen plasma (ST310), thereby removing the thinner resist pattern 20. At this time, the thicker resist pattern 19 is thinned into a resist pattern 19a as shown in FIG. 6F. Then, the second metal film 8 is wet etched for the second time with the masking resist pattern 19a (ST311). Like at the first time, the etchant containing cerium diammonium nitrate and perchloric acid can be used. As such, at a part of which the resist pattern 20 has been removed, the second metal film 8 is etched so that the transparent conductive film 7 is exposed as shown in FIG. 6G. That is, the transmissive pixel electrode 10a is formed in a pixel electrode portion. Then, the resist pattern 19a is removed by stripping off, and the whole is cleaned with pure water (ST312). By this means, the drain electrodes 9a, 9b, the transmissive pixel electrode 10a, the source electrodes 11a, 11b, the source terminals 13a, 13b, and the source lines 44a, 44b are obtained as shown in FIG. 6H.

Next, a semiconductor film is formed over these (ST313) As the semiconductor film, an amorphous silicon film is formed to a thickness of 150 nm with use of the CVD method. Then, a third photolithography process is performed (ST314), thereby forming a resist pattern on the semiconductor film. The amorphous silicon film is etched by use of a dry etching method using fluorine-based gas (ST315). Then, the resist pattern is removed by stripping off, and the whole is cleaned with pure water (ST316). By this means, the semiconductor film 21 having a channel region 22 is formed as shown in FIG. 6I (ST316).

A second insulating film as a passivation film 23 is formed over the semiconductor film 21 (ST317). Here, a silicon nitride film (SiN film) of 300 nm in thickness is formed using the CVD method. Thereafter, a fourth photolithography process is performed (ST318). Then, the passivation film 23 is etched by dry etching (ST319) which uses, e.g., fluorine-based gas. The passivation film 23 is partially removed down to the surface of the source terminal 13 to form a source terminal opening 25. Also, the passivation film 23 and the gate insulating film 6 are both partially removed down to the surface of the gate terminal 4 to form a gate terminal opening 24. Finally, the resist pattern is removed by stripping off, and the whole is cleaned with pure water (ST320). By this means, a TFT array substrate 61 of a bottom-gate type is completed as shown in FIG. 6J.

As described above, in the present embodiment, the semiconductor film 21 is formed over the drain electrode 9 and the source electrode 11. The formation of the transmissive pixel electrode 10a and the formation of the drain electrode 9, the source electrode 11, the source terminal 13, and the source line 44 are consolidated into one photolithography process. By this means, the TFT array substrate 61 can be manufactured with the four-mask process without consolidating the formation of the channel region 22 into the photolithography process for the formation of the drain electrode 9 and the source electrode 11. That is, with realizing the four-mask process, the formation of the channel region 22 is performed with use of a photolithography process separate from the formation of the drain electrode 9 and the source electrode 11. When patterning the semiconductor film to form the channel region, multiphase exposure such as halftone or gray tone is not used. The thinner portion of the resist pattern having difference in film thickness is formed on the region where the transmissive pixel electrode 10a is to be formed. Because no thinner portion of the resist pattern is formed over the region between the drain electrode 9 and the source electrode 11, the distance between the drain electrode 9 and the source electrode 11 can be easily controlled. That is, since part of the semiconductor film 21 that is between the drain electrode 9 and the source electrode 11 is the channel region 22, the channel length of the TFT is determined by the distance between the drain electrode 9 and the source electrode 11. Therefore, the control of the channel length is easier, and thus variation in channel length can be suppressed. Further, the occurrence of display unevenness due to variation in channel length is suppressed, and display quality and yield can be improved without increasing the number of photolithography processes. Yet further, since the drain electrode 9 and the source electrode 11 are constituted by the stacked layer of the transparent conductive film 7 and the second metal film 8, there is the effect that the resistance of the source line 44 can be reduced as compared to a single layer of the transparent conductive film 7.

In the present embodiment, the case where a Cr film is formed as the second metal film 8 has been described illustratively, but a Ti film may be formed. In this case, the drain electrode 9b, the source electrode 11b, the source terminal 13b, and the source line 44b are formed by the Ti film. When a Ti film is used for the drain electrode 9b and the source electrode 11b, charges smoothly transfer through their interface junction with the semiconductor film 21, thus improving electrical contact characteristics. Therefore, TFT characteristics such as charge mobility and ON current can be improved. If a Ti film is used as the second metal film 8, at ST308 and ST311, etching is performed with use of an etchant containing hydrofluoric acid and nitric acid. Note that because the etchant containing hydrofluoric acid and nitric acid cannot perform selective etching between a Ti film and a-Si semiconductor film, it is difficult to form source/drain electrodes of a Ti film with use of wet etching using the etchant containing hydrofluoric acid and nitric acid, with the configuration where the semiconductor film 21 is formed underneath the drain electrode 9 and the source electrode 11 as in the Japanese Unexamined Patent Application Publications No. 08-50308 and No. 2005-283689. That is, with the configuration of the present embodiment, a Ti film can be used suitably as the second metal film 8 because the drain electrode 9 and the source electrode 11 are formed before the semiconductor film 21 is formed.

Alternatively, an Al film can be used as the second metal film 8. At this time, if an ITO film is used as the transparent conductive film 7, an Al-ITO battery reaction will occur when the photoresist 14 is developed with an organic developer, and thereby the transparent conductive film 7 may be blacked due to reductive corrosion to lose optical transparency. In this case, if an Al alloy film with at least one element of Fe, Co, Ni, and Pt from among group 8 elements of the periodic table being added is used as the second metal film 8, battery reaction with the ITO film in the developer can be suppressed. In order to suppress battery reaction, the additive amount of the element is preferably at or above 0.5 mol % (0.5 atm %). However, as the additive amount of the element increases, electrical resistivity increases. Hence, in order to make its resistivity equal to or less than that of the Cr film, the additive amount is preferably less than 15 mol % (15 atm %)

### Embodiment 2

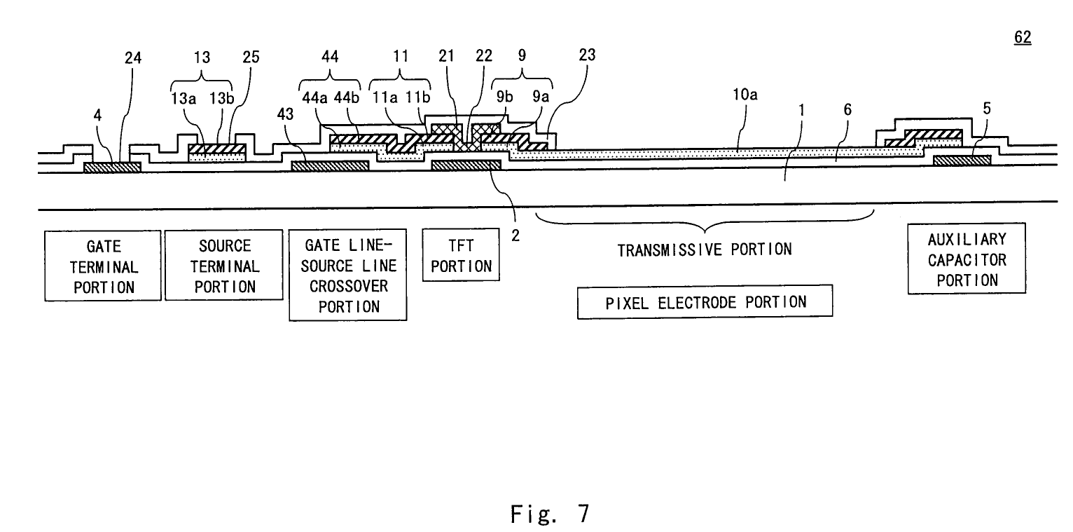

Next, the configuration of a TFT array substrate 62 according to the present embodiment 2 will be described using FIG. 7. The present embodiment differs from embodiment 1 in the configuration of the pixel electrode portion and is the same in the other configurations as embodiment 1, and hence description thereof is omitted. FIG. 7 shows a cross-sectional structure of the TFT array substrate 62 according to the present embodiment 2. In FIG. 7, the present embodiment has the configuration of the pixel electrode portion where the surface of the transmissive pixel electrode 10a is exposed.

The TFT array substrate 62 of such a configuration is formed by removing part of the passivation film 23 that is on the transmissive pixel electrode 10a in the same way as for the source terminal opening 25, in the formation process (ST317 to ST320) of the passivation film 23. Because the other processes are the same as in embodiment 1, description thereof is omitted. As in embodiment 1, in the present embodiment the semiconductor film 21 is formed over the drain electrode 9 and the source electrode 11.

As mentioned above, in the present embodiment the passivation film 23 is not formed on the transmissive pixel electrode 10a so that the transmissive pixel electrode 10a is exposed. By this means, optical transmittance in the pixel electrode portion is improved, thus improving display brightness. Further, with realizing the four-mask process, the formation of the channel region 22 is performed with use of a photolithography process separate from the formation of the drain electrode 9 and the source electrode 11. When patterning the semiconductor film to form the channel region, multiphase exposure such as halftone or gray tone is not used. Because no thinner portion of the resist pattern is formed over the region between the drain electrode 9 and the source electrode 11, the distance between the drain electrode 9 and the source electrode 11 can be easily controlled. Therefore, the control of the channel length is easier, and thus variation in channel length can be suppressed.

### Embodiment 3

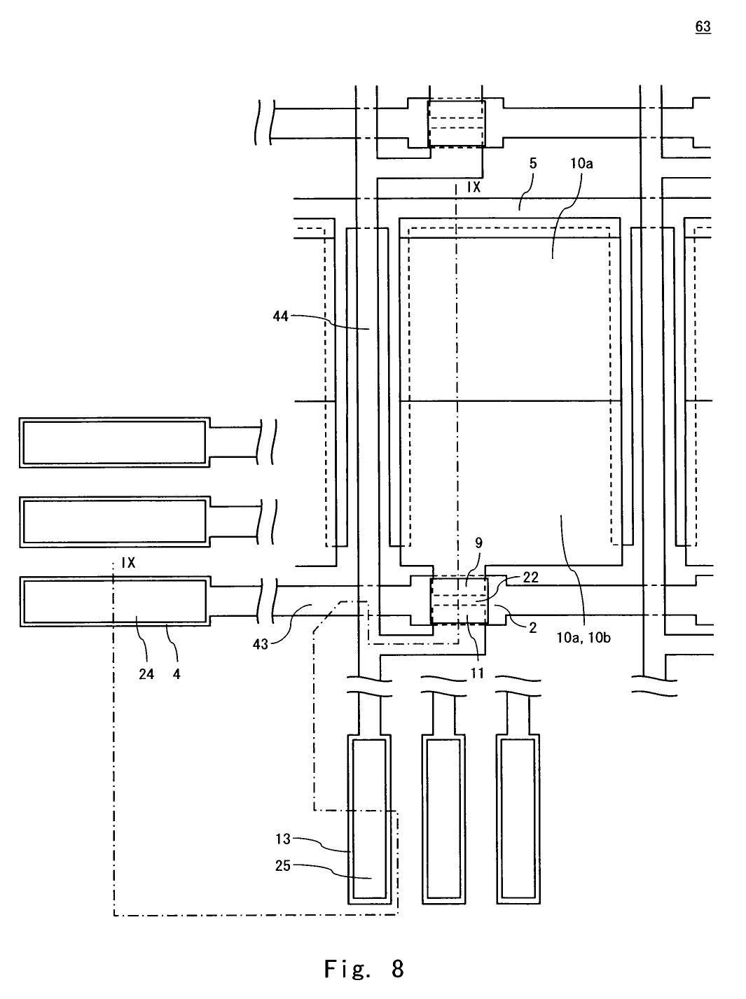

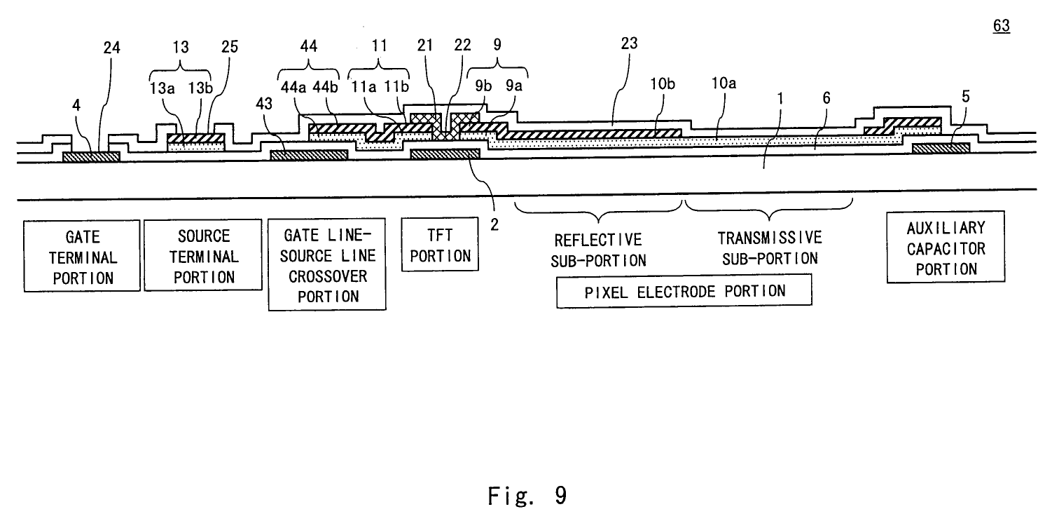

A TFT array substrate 63 according to the present embodiment 3 will be described using FIGS. 8 and 9. The present embodiment differs from embodiments 1, 2 in the configuration of the pixel electrode portion and is the same in the other configurations as embodiments 1, 2, and hence description thereof is omitted. The TFT array substrates of embodiments 1, 2 are ones used in, e.g., transmissive liquid crystal displays, whose pixel electrode portion consists of a transmissive portion. The TFT array substrate of the present embodiment is used in, e.g., transflective liquid crystal displays, and its pixel electrode portion consists of a transmissive sub-portion and a reflective sub-portion. FIG. 8 is a plan view of the TFT array substrate 63 according to the present embodiment 3, and FIG. 9 is a sectional view on line IX-IX of FIG. 8. In FIG. 8, only contact holes are shown as to the gate insulating film 6 and the passivation film 23.

As shown in FIGS. 8 and 9, the TFT array substrate 63 has a pixel electrode portion consisting of a transmissive sub-portion and a reflective sub-portion. In the reflective sub-portion, the second metal film 8 is formed extending from the drain electrode 9b. That is, in the reflective sub-portion, a transmissive pixel electrode 10a of the transparent conductive film 7 is formed on the gate insulating film 6, and further a reflective pixel electrode 10b of the second metal film 8 is formed. Part of the transmissive pixel electrode 10a extending out from under the reflective pixel electrode 10b is the transmissive sub-portion. That is, the transmissive pixel electrode 10a is formed extending over the entire pixel electrode portion from the drain electrode 9a, and the reflective pixel electrode 10b is formed extending over part of the pixel electrode portion from the drain electrode 9b. As in embodiments 1, 2, in the present embodiment the semiconductor film 21 is formed over the drain electrode 9 and the source electrode 11.

The TFT array substrate 63 of such a configuration is formed by using a photomask 18 having a different pattern from that of embodiments 1, 2 in the second photolithography process (ST307). The thicker resist pattern 19 is formed on the region where the reflective pixel electrode 10b is to be provided as well as the regions where the drain electrode 9, the source electrode 11, and the source line 44 are to be provided. If the photoresist 14 is, for example, a novolac resin-based positive resist, a photomask 18 is used which has the shielding portions 17 to shield the region where the reflective pixel electrode 10b is to be formed as well as the regions for the drain electrode 9, the source electrode 11, the source terminal 13, and the source line 44.

Then, after the first wet etching of the second metal film 8 (ST308) and the wet etching of the transparent conductive film 7 (ST309), ashing is performed (ST310) as in embodiments 1, 2. At this time, the thinner resist pattern 20 on the transmissive sub-portion of the pixel electrode portion is removed. The thicker resist pattern 19 on the drain electrode 9, the source electrode 11, the source terminal 13, the source line 44, and the reflective pixel electrode 10b is thinned into a resist pattern 19a. The second metal film 8 is wet etched for the second time with the masking resist pattern 19a (ST311), so that the transparent conductive film 7 is exposed at only the transmissive sub-portion of the pixel electrode portion. Finally, the resist pattern 19a is removed by stripping off (ST312), so that both the reflective sub-portion and the transmissive sub-portion are formed in one pixel electrode portion.

As described above, in the present embodiment, the second metal film 8 extending over part of the pixel electrode portion from the drain electrode 9b forms the reflective pixel electrode 10b. By this means, the TFT array substrate 63 for use in transflective liquid crystal displays can be formed which has the reflective sub-portion and the transmissive sub-portion in one pixel electrode portion. Further, with realizing the four-mask process, the formation of the channel region 22 is performed with use of a photolithography process separate from the formation of the drain electrode 9 and the source electrode 11. When patterning the semiconductor film to form the channel region, multiphase exposure such as halftone or gray tone is not used. Because no thinner portion of the resist pattern is formed over the region between the drain electrode 9 and the source electrode 11, the distance between the drain electrode 9 and the source electrode 11 can be easily controlled. Therefore, the control of the channel length is easier, and thus variation in channel length can be suppressed.

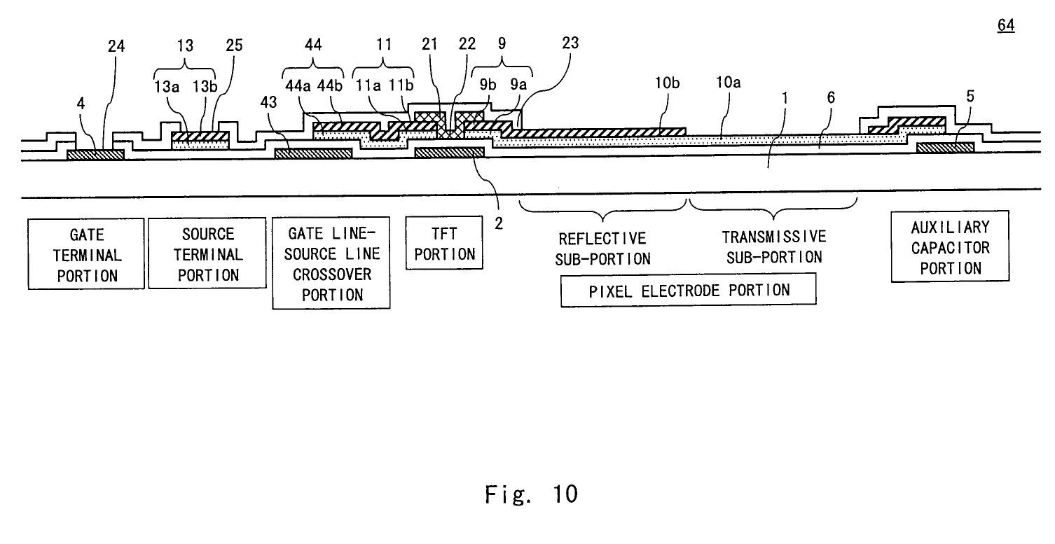

Also in the present embodiment, as in embodiment 2, part of the passivation film 23 that is on the pixel electrode portion may be removed. FIG. 10 shows a cross-sectional structure of a TFT array substrate 64 according to another example of the present embodiment 3. As shown in FIG. 10, the passivation film 23 is not formed on the pixel electrode portion so that part of the transmissive pixel electrode 10a and the reflective pixel electrode 10b are exposed. By this means, optical transmittance is improved, thus improving display brightness.

### Embodiment 4

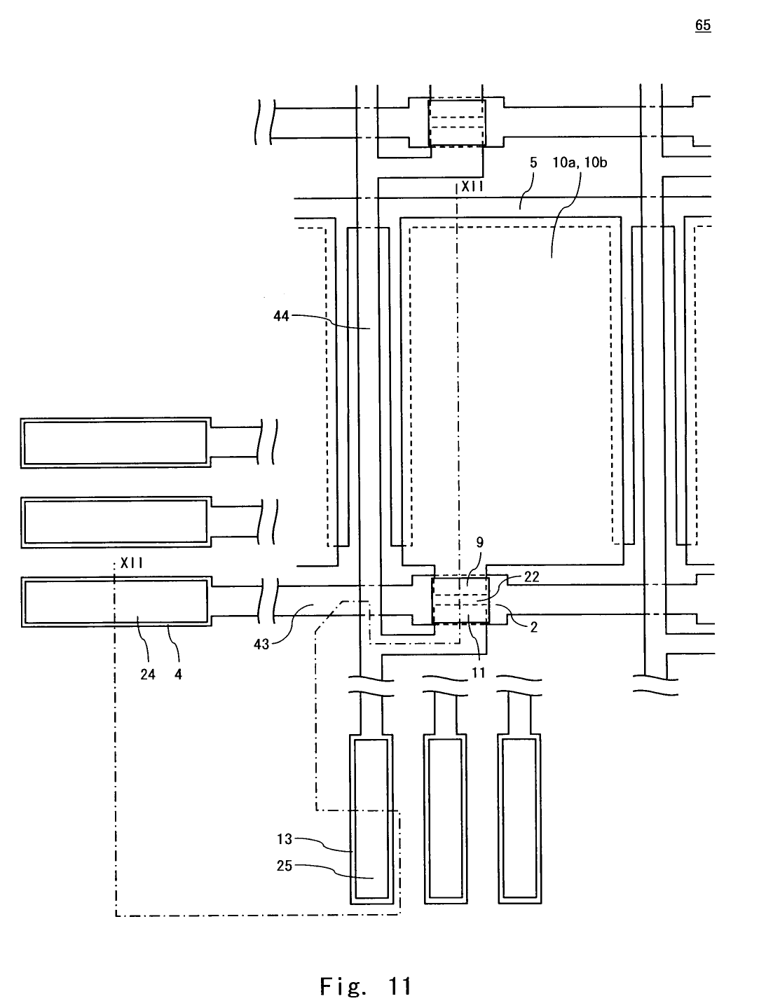

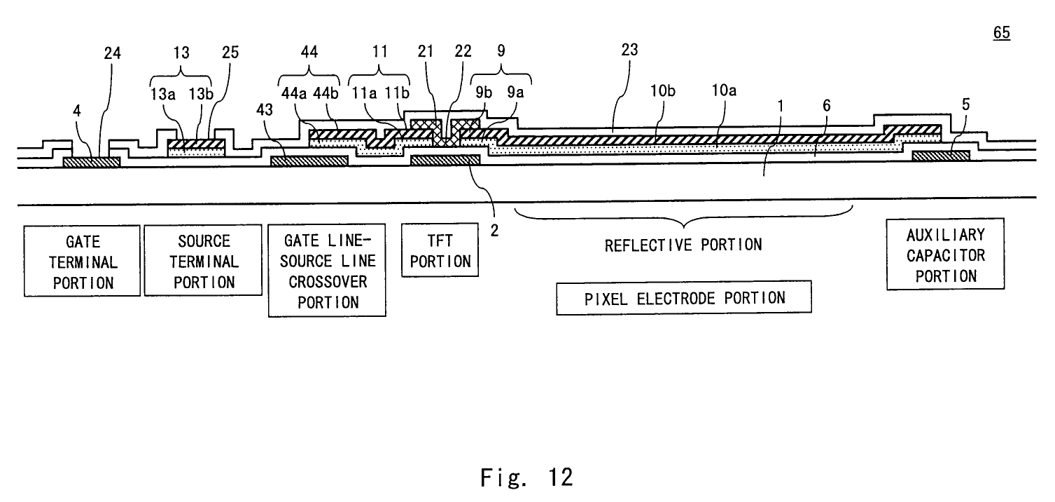

A TFT array substrate 65 according to the present embodiment 4 will be described using FIGS. 11 and 12. The present embodiment differs from embodiments 1 to 3 in the configuration of the pixel electrode portion and is the same in the other configurations as embodiments 1 to 3, and hence description thereof is omitted. The TFT array substrates of embodiments 1, 2 are ones used in, e.g., transmissive liquid crystal displays, whose pixel electrode portion consists of a transmissive portion. The TFT array substrate of embodiment 3 is one used in, e.g., transflective liquid crystal displays, whose pixel electrode portion consists of a transmissive sub-portion and a reflective sub-portion. In contrast, the TFT array substrate of the present embodiment is used in, e.g., reflective liquid crystal displays, and its pixel electrode portion consists of a reflective portion. FIG. 11 is a plan view of the TFT array substrate 65 according to the present embodiment 4, and FIG. 12 is a sectional view on line XII-XII of FIG. 11. In FIG. 11, only contact holes are shown as to the gate insulating film 6 and the passivation film 23.

As shown in FIGS. 11 and 12, no transmissive portion is formed in the pixel electrode portion of the present embodiment, differing from embodiments 1 to 3. That is, the pixel electrode portion of the TFT array substrate 65 consists of a reflective portion, and the second metal film 8 extending from the drain electrode 9b forms the reflective pixel electrode 10b. The reflective pixel electrode 10b is formed on the entire transmissive pixel electrode 10a. As in embodiments 1 to 3, in the present embodiment the semiconductor film 21 is formed over the drain electrode 9 and the source electrode 11.

The TFT array substrate 65 of such a configuration may be formed with a usual photolithography process without using the halftone or gray tone exposure technique in the second photolithography process (ST307). In this case, the resist ashing (ST310) and the second wet etching of the second metal film (ST311) are not performed.

As described above, in the present embodiment, the second metal film 8 extending over the entire pixel electrode portion from the drain electrode 9b forms the reflective pixel electrode 10b. By this means, the TFT array substrate 65 whose pixel electrode portion consists of a reflective portion is formed for use in reflective liquid crystal displays. Further, with realizing the four-mask process, the formation of the channel region 22 is performed with use of a photolithography process separate from the formation of the drain electrode 9 and the source electrode 11. When patterning the semiconductor film to form the channel region, multiphase exposure such as halftone or gray tone is not used. Because no thinner portion of the resist pattern is formed over the region between the drain electrode 9 and the source electrode 11, the distance between the drain electrode 9 and the source electrode 11 can be easily controlled. Therefore, the control of the channel length is easier, and thus variation in channel length can be suppressed.

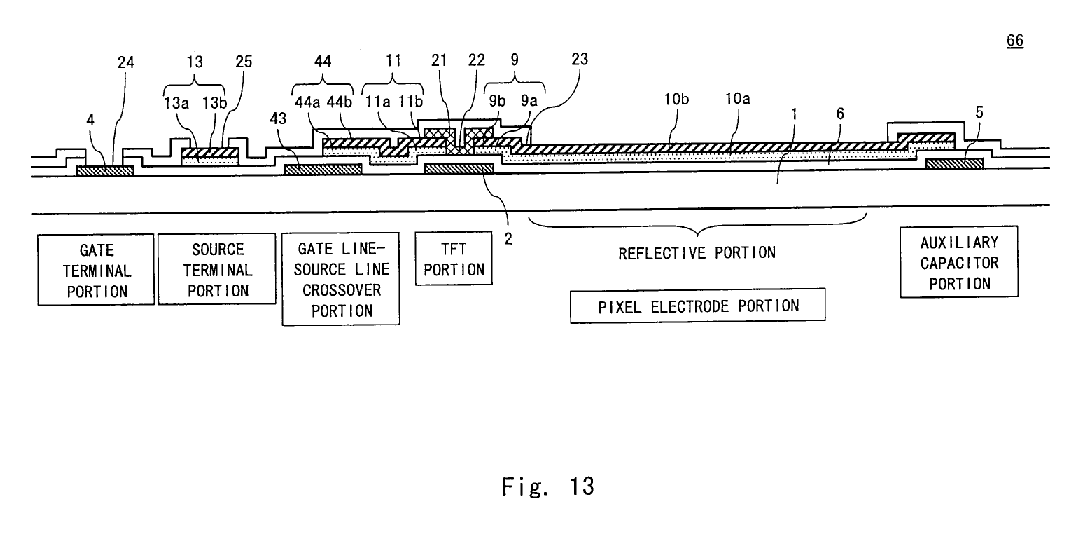

Also in the present embodiment, as in embodiment 2, part of the passivation film 23 that is on the pixel electrode portion may be removed. FIG. 13 shows a cross-sectional structure of a TFT array substrate 66 according to another example of the present embodiment 4. As shown in FIG. 13, the passivation film 23 is not formed on the pixel electrode portion so that the reflective pixel electrode 10b is exposed. By this means, optical transmittance is improved, thus improving display brightness.

### Embodiment 5

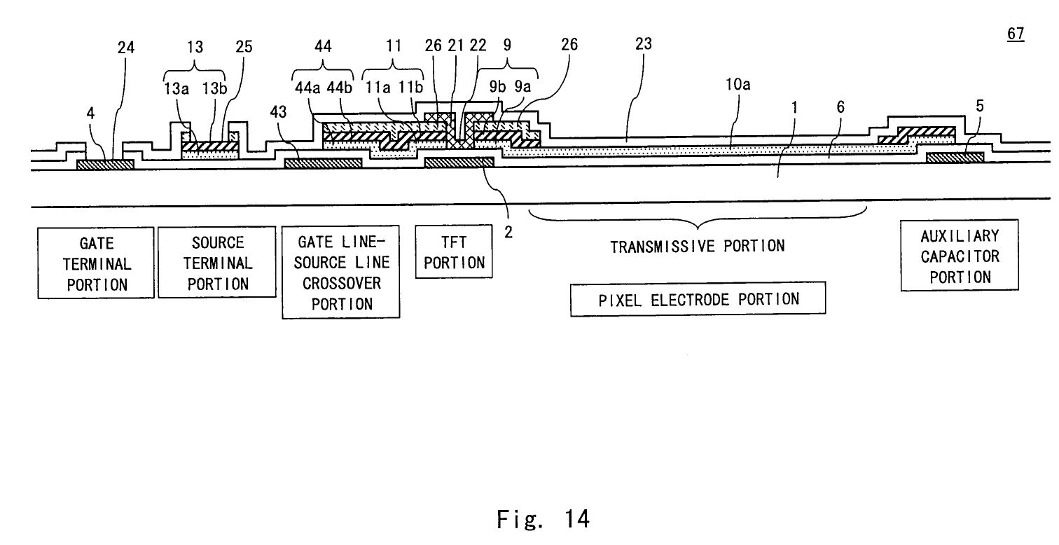

A TFT array substrate 67 according to the present embodiment 5 will be described using FIG. 14. The TFT array substrate of the present embodiment is configured to have one more layer than embodiments 1 to 4 and is the same in the other configurations as embodiments 1 to 4, and hence description thereof is omitted. FIG. 14 shows a cross-sectional structure of a TFT array substrate 67 according to the present embodiment 5.

In FIG. 14, an ohmic contact film 26 is formed between the semiconductor film 21 and the drain electrode 9, and between the semiconductor film 21 and the source electrode 11. The ohmic contact film 26 is formed on at least the drain electrode 9b and the source electrode 11b and electrically connects these electrodes to the semiconductor film 21 respectively. In the TFT array substrate 67 of FIG. 14, the ohmic contact film 26 is formed also on part of the source terminal 13b and the source line 44b.

The TFT array substrate 67 of such a configuration is formed by, after forming the transparent conductive film 7 and the second metal film 8 over the gate insulating film 6 at ST306, further forming the ohmic contact film 26 thereon. An n+ amorphous silicon (n+ a-Si) film with, e.g., phosphorus added as an impurity is formed as the ohmic contact film 26 with use of the CVD method. The steps preceding ST306 are the same as in embodiments 1 to 4, and hence description thereof is omitted.

After the ohmic contact film 26 is formed, at ST307 the second photolithography process is performed using a photomask 18 as in embodiments 1 to 4. The first etching of the ohmic contact film 26 is performed before or at the same time as the first etching of the second metal film 8 (ST308). Then, after at ST309 the transparent conductive film 7 is patterned by etching, at ST310 the thinner resist pattern 20 is removed by resist ashing. Subsequently, the exposed part of the ohmic contact film 26 after the removal of the resist pattern 20 and the second metal film 8 under it are removed by etching. This second etching of the ohmic contact film 26 may also be performed before or at the same time as the second etching of the second metal film 8 (ST311). Finally, the resist pattern 19a is removed by stripping off at ST312. In this way, the ohmic contact film 26 is formed on the drain electrode 9b, the source electrode 11b, the source terminal 13b, and the source line 44b.

At ST313 to ST316, the semiconductor film 21 is formed over the ohmic contact film 26 formed on the drain electrode 9b and the source electrode 11b. Then, at ST317 to ST320, the passivation film 23 is formed, and at this time, the source terminal opening 25 is formed by removing the ohmic contact film 26 on the source terminal 13b together with the passivation film 23.

As described above, in the present embodiment the ohmic contact film 26 is formed between the semiconductor film 21 and the drain electrode 9, and between the semiconductor film 21 and the source electrode 11. With this configuration, electrical conduction between the semiconductor film 21 and the drain electrode 9 and between the semiconductor film 21 and the source electrode 11 of a TFT can be improved, thus improving TFT characteristics. Therefore, the occurrence of display defects due to operational failures of TFTs can be reliably prevented, and the display quality of display devices can be improved. Further, with realizing the four-mask process, the formation of the channel region 22 is performed with use of a photolithography process separate from the formation of the drain electrode 9 and the source electrode 11. When patterning the semiconductor film to form the channel region, multiphase exposure such as halftone or gray tone is not used. Because no thinner portion of the resist pattern is formed over the region between the drain electrode 9 and the source electrode 11, the distance between the drain electrode 9 and the source electrode 11 can be easily controlled. Therefore, the control of the channel length is easier, and thus variation in channel length can be suppressed.

Although in the present embodiment the case where the n+ a-Si film is formed as the ohmic contact film 26 has been described illustratively, electrically conductive, opaque metal oxide can be used. For example, a film of chromium oxide CrOₓ, where x is a positive number, made by adding oxygen atoms in such an amount as to secure conductivity may be used as the ohmic contact film 26. After a Cr film is formed as the second metal film 8 by use of the sputtering method using Ar gas, a CrOₓ film is formed by a reactive sputtering method using a mixture gas of Ar and O₂. Alternatively, after a Cr film is formed, a CrOₓ film may be formed by oxygen plasma processing which irradiates plasma including oxygen gas onto the surface of the Cr film.

Also, electrically conductive, opaque metal nitride can be used as the ohmic contact film 26. For example, a film of chromium oxide CrNₓ, where x is a positive number, made by adding nitrogen atoms in such an amount as to secure conductivity may be used as the ohmic contact film 26. After a Cr film is formed as the second metal film 8 by use of the sputtering method using Ar gas, a CrNₓ film is formed by a reactive sputtering method using a mixture gas of Ar and N₂. Alternatively, after a Cr film is formed, a CrNₓ film may be formed by nitrogen plasma processing which irradiates plasma including nitrogen gas onto the surface of the Cr film.

### Embodiment 6

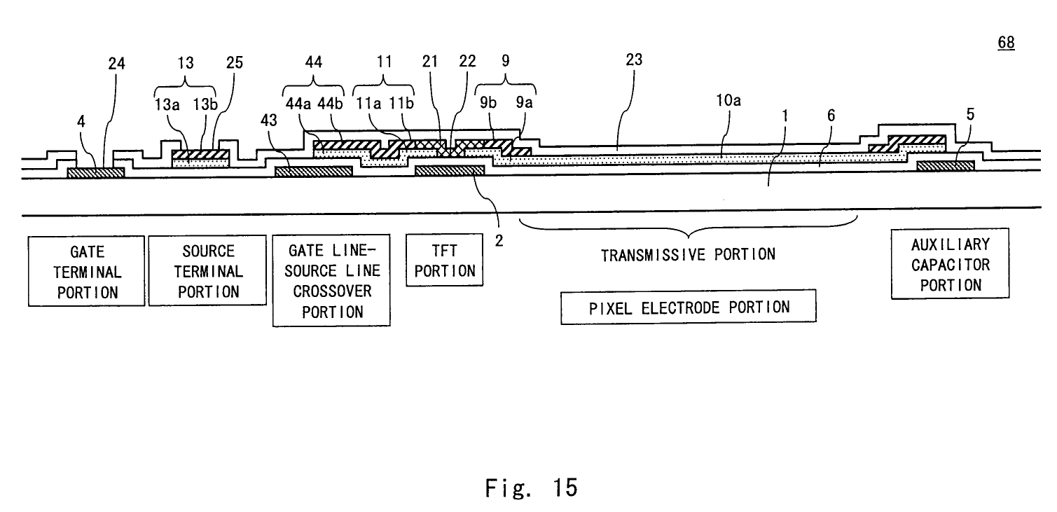

A TFT array substrate 68 according to the present embodiment 6 will be described using FIG. 15. The TFT array substrate of the present embodiment differs from embodiments 1 to 4 in the configuration of the TFT portion and is the same in the other configurations as embodiments 1 to 4, and hence description thereof is omitted. FIG. 15 shows a cross-sectional structure of a TFT array substrate 68 according to the present embodiment 6.

As shown in FIG. 15, a drain electrode 9b smaller than the drain electrode 9a is formed on the drain electrode 9a, and hence there is part of the drain electrode 9a which the drain electrode 9b does not cover. This part is preferably located on the source electrode 11 side of the drain electrode 9a. That is, the drain electrode 9b does not extend to the edge of the drain electrode 9a on the semiconductor film 21 side thereof. Likewise, a source electrode 11b smaller than the source electrode 11a is formed on the source electrode 11a, and hence there is part of the source electrode 11a which the source electrode 11b does not cover. This part is preferably located on the drain electrode 9 side of the source electrode 11a. That is, the source electrode 11b does not extend to the edge of the source electrode 11a on the semiconductor film 21 side thereof. The semiconductor film 21 is formed on the drain electrode 9a, the source electrode 11a, and the region between these electrodes.

FIG. 15 schematically shows an example configuration where the edges of the semiconductor film 21 are completely in contact with the edges of the source electrode 11b and of the drain electrode 9b, but not being limited to this, the semiconductor film 21 may be formed spaced away from the source electrode 11b and the drain electrode 9b, or the semiconductor film 21 may overlap onto the source electrode 11b and the drain electrode 9b. The underside of the semiconductor film 21 need only be in contact with the source electrode 11a and the drain electrode 9a.

The TFT array substrate 68 of such a configuration is formed by using a photomask 18 having a different pattern from that of embodiments 1 to 4 in the second photolithography process (ST307). The thinner resist pattern 20 is formed on the regions where the drain electrode 9b is not to be formed on the drain electrode 9a and the source electrode 11b is not to be formed on the source electrode 11a as well as the region where the transmissive pixel electrode 10a is to be provided. If the photoresist 14 is, for example, a novolac resin-based positive resist, a photomask 18 is used which has the second exposure portions 16 corresponding to the regions where the drain electrode 9b is not to be formed on the drain electrode 9a and the source electrode 11b is not to be formed on the source electrode 11a as well as the region for the transmissive pixel electrode 10a.

With this configuration, electrical connection between the semiconductor film 21 and the drain electrode 9 is made via the drain electrode 9a as well as the drain electrode 9b, and electrical connection between the semiconductor film 21 and the source electrode 11 is made via the source electrode 11a as well as the source electrode 11b. That is, electrical connection between the semiconductor film 21 and the drain electrode 9 and between the semiconductor film 21 and the source electrode 11 is made via the transparent conductive film 7 as well as the second metal film 8. Therefore, electrical conduction between the semiconductor film 21, and the drain electrode 9 and source electrode 11 of a TFT can be improved, thus improving TFT characteristics. Therefore, the occurrence of display defects due to operational failures of TFTs can be reliably prevented and the display quality of display devices can be improved. Further, with realizing the four-mask process, the formation of the channel region 22 is performed with use of a photolithography process separate from the formation of the drain electrode 9 and the source electrode 11. When patterning the semiconductor film to form the channel region, multiphase exposure such as halftone or gray tone is not used. Because no thinner portion of the resist pattern is formed over the region between the drain electrode 9 and the source electrode 11, the distance between the drain electrode 9 and the source electrode 11 can be easily controlled. Therefore, the control of the channel length is easier, and thus variation in channel length can be suppressed.

### Embodiment 7

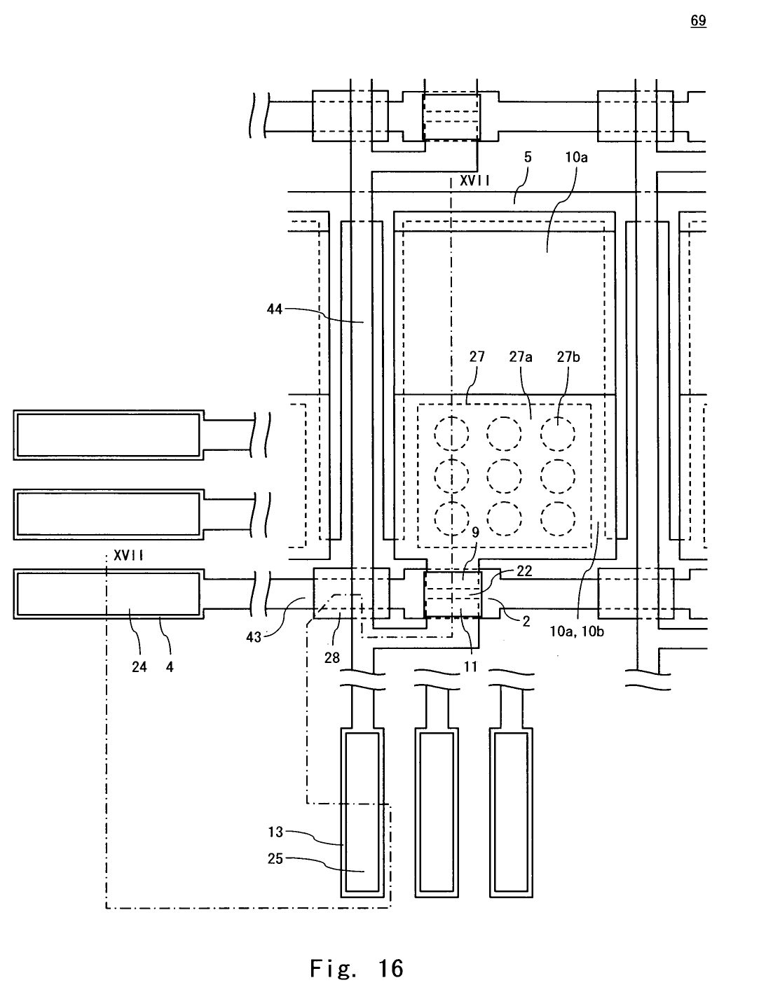

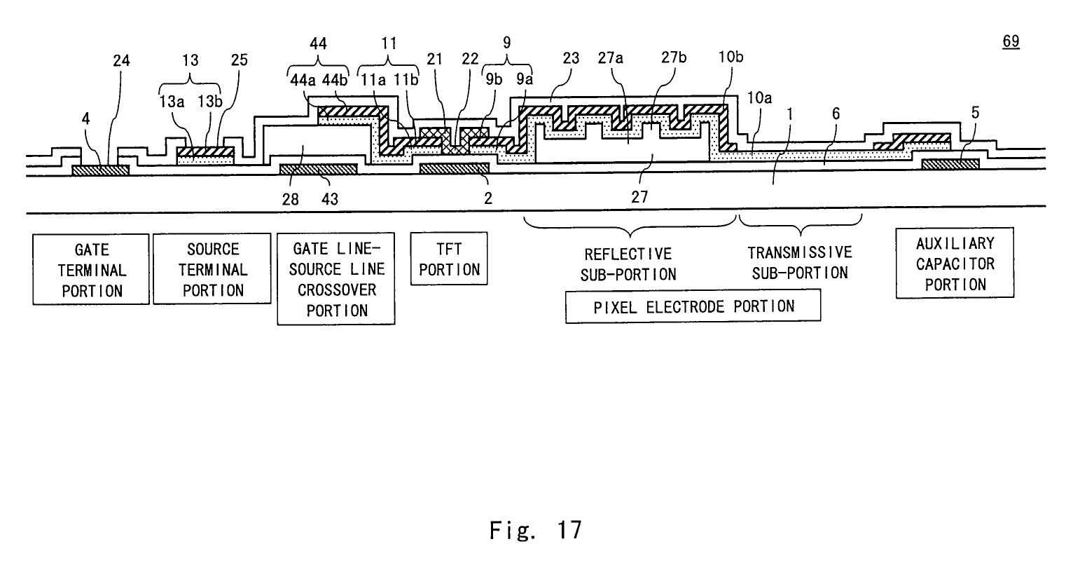

A TFT array substrate 69 according to the present embodiment 7 will be described using FIGS. 16 and 17. The TFT array substrate of the present embodiment is configured to further have a raise/recess pattern on the TFT array substrate 63 of embodiment 3 and is the same in the other configurations as embodiment 3, and hence description thereof is omitted. FIG. 16 is a plan view of the TFT array substrate 69 according to the present embodiment 7, and FIG. 17 is a sectional view on line XVII-XVII of FIG. 16. In FIG. 16, only contact holes are shown as to the gate insulating film 6 and the passivation film 23.

In FIGS. 16 and 17, the same reference numerals indicate the same components as in FIGS. 8 and 9, and their differences will be described. In FIGS. 16 and 17, the TFT array substrate 69 has a pixel electrode portion consisting of a transmissive sub-portion and a reflective sub-portion as in embodiment 3. In the present embodiment, a raise/recess pattern 27 having raises/recesses is formed in between the gate insulating film 6 and the transmissive pixel electrode 10a in the reflective sub-portion. That is, the raise/recess pattern 27 is formed on the gate insulating film 6 in the reflective sub-portion. The raise/recess pattern 27 has recesses 27a and raises 27b provided in its surface.

As in embodiment 3, the transmissive pixel electrode 10a is formed extending over the entire pixel electrode portion from the drain electrode 9a. The reflective pixel electrode 10b is formed extending over part of the pixel electrode portion from the drain electrode 9b. That is, the transmissive pixel electrode 10a made of the transparent conductive film 7 is formed covering the raise/recess pattern 27. The reflective pixel electrode 10b of the second metal film 8 is further formed on the transmissive pixel electrode 10a in the reflective sub-portion. That is, the raise/recess pattern 27 is formed to be covered by the reflective pixel electrode 10b. Thus, the reflective pixel electrode 10b is formed to have raises and recesses corresponding to the raise/recess pattern 27. The raises and recesses of the reflective pixel electrode 10b effectively scatter external light, thereby improving the display characteristic of the reflective sub-portion.

The raise/recess pattern 27 is preferably formed by, for example, a photosensitive resin film such as a resist. Here, the raise/recess pattern 27 is an acrylic-based organic resin film. By using the acrylic-based organic resin film for the raise/recess pattern 27, the endurance of its raises and recesses can be improved, thus improving display quality. The raise/recess pattern 27 may be formed by an inorganic film as long as the film is an insulating one, not being limited to an organic film.

The pattern size of the reflective pixel electrode 10b is made larger than that of the raise/recess pattern 27, so that the ends of the raise/recess pattern 27 are located inward of the ends of reflective pixel electrode 10b. That is, the raise/recess pattern 27 is not formed in the transmissive sub-portion where the reflective pixel electrode 10b is not provided. With this configuration, transparency to transmitted display light is kept at the same level as in embodiment 3. At the same time, the optical path lengths of reflected display light and of transmitted display light can be adjusted using the step formed between the reflective sub-portion and the transmissive sub-portion, thus improving display characteristics.

Further, in the present embodiment an insulating pattern 28 that is the same layer as the raise/recess pattern 27 is formed in a gate line-source line crossover portion. The insulating pattern 28 is formed on the gate insulating film 6 so as to cover the gate line 43 in the gate line-source line crossover portion. Thus, the source line 44 crosses over the gate line 43, with the gate insulating film 6 and the insulating pattern 28 interposed therebetween. By this means, even if a failure in the coverage of the gate insulating film 6 occurs at an edge of the gate line 43, a short-circuit failure between the gate line 43 and the source line 44 can be prevented.

Moreover, as in embodiments 1 to 4, in the present embodiment, the semiconductor film 21 is formed over the drain electrode 9 and the source electrode 11.

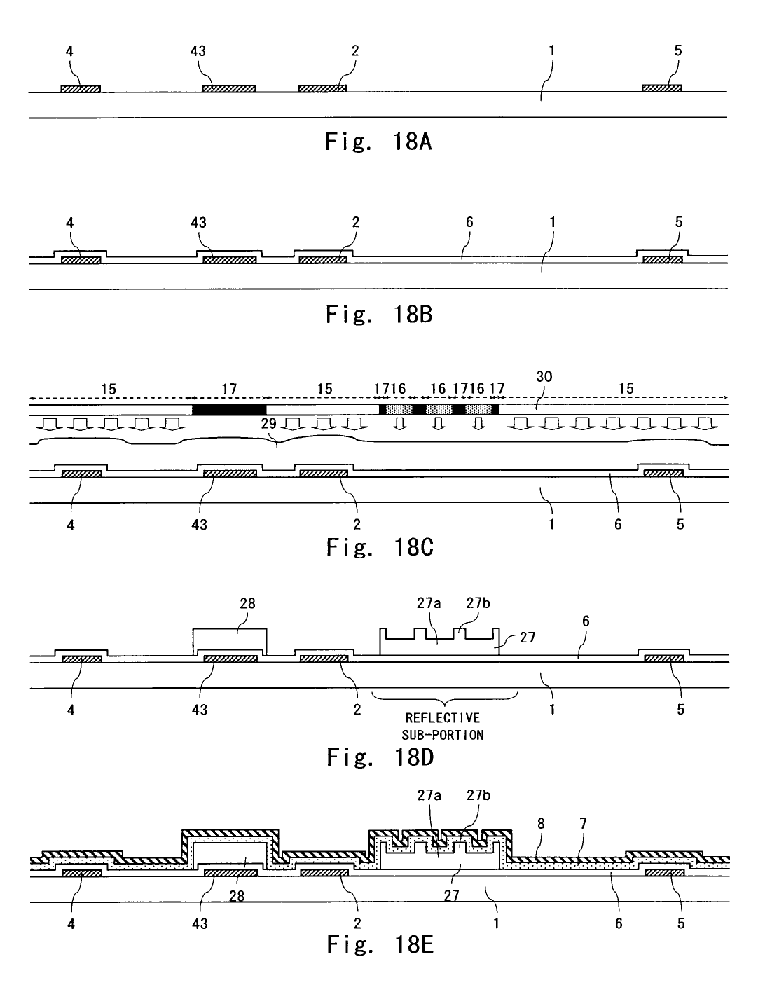

Here, the method of manufacturing the TFT array substrate 69 according to the present embodiment will be described with reference to FIGS. 18A to 18E, 19F to 19I, and 20J to 20M. FIGS. 18A to 18E, 19F to 19I, and 20J to 20M are sectional views showing the manufacturing process for the TFT array substrate 69 according to the present embodiment 7. In the present embodiment, the process for forming the raise/recess pattern 27 is performed in addition to the manufacturing process for the TFT array substrate 63 according to embodiment 3. The other processes are the same as in embodiment 3, and hence detailed description thereof is omitted.

As in embodiment 3, first, an insulating substrate 1 is cleaned with pure water (ST301). Thereafter, a first metal film is formed on the entire insulating substrate 1 (ST302). Next, a first photolithography process is performed (ST303), thereby forming a resist pattern on the first metal film. Then, wet etching is performed with this masking resist pattern (ST304), thereby patterning the first metal film. Thereafter, the resist pattern is removed by stripping off, and the whole is cleaned with pure water (ST305). In this way, the gate electrode 2, the gate line 43, the gate terminal 4, and the auxiliary capacitor electrode 5 are formed as shown in FIG. 18A.

The present embodiment greatly differs from embodiment 3 in the subsequent step ST306, which will be described in detail. The gate insulating film 6 as a first insulating film is formed on the entire insulating substrate 1 so as to cover the gate electrode 2, the gate line 43, the gate terminal 4, and the auxiliary capacitor electrode 5. After the formation of the gate insulating film 6, in the present embodiment a second photolithography process is performed to form the raise/recess pattern 27. Here, the case of using an acrylic-based organic resin film for the raise/recess pattern 27 will be described, but another photosensitive resin film such as a resist may be used. First, an organic resin film 29 is coated to a thickness of about 3.6 μm using a spin coat method. The organic resin film 29 can be an acrylic-based organic resin film having positive photosensitivity. By this means, the organic resin film 29 is formed on the gate insulating film 6 as shown in FIG. 18B.

Subsequently, as shown in FIG. 18C, the organic resin film 29 is exposed to light. At this time, the multiphase exposure is performed using a photomask 30 that has the first exposure portions 15, the second exposure portions 16, and the shielding portions 17 as the photomask 18 used at ST307 shown in FIG. 5C. When, for example, the positive organic resin film 29 is used, the photomask 30 is provided with the shielding portions 17 corresponding to the regions where the raises 27b of the raise/recess pattern 27 and the insulating pattern 28 are to be formed and provided with the second exposure portions 16 corresponding to the regions where the recesses 27a of the raise/recess pattern 27 are to be formed. After the organic resin film 29 is exposed to light with this photomask 30, the film 29 is developed with an organic alkali-based developer. Thereby, parts of the organic resin film 29 corresponding to the first exposure portions 15 are removed so that the gate insulating film 6 is exposed, while a pattern of thicker portions of the organic resin film 29 is formed corresponding to the shielding portions 17 and a pattern of thinner portions of the organic resin film 29 is formed corresponding to the second exposure portions 16. Thus, as shown in FIG. 18D, the raise/recess pattern 27 having raises/recesses is formed on the region which is to be the reflective sub-portion. That is, the recesses 27a and the raises 27b, which are different in thickness, are formed at the same time. Together with the raise/recess pattern 27, the insulating pattern 28 covering the gate line 43 is formed on the region which is to be the gate line-source line crossover portion.

After the formation of the raise/recess pattern 27 and the insulating pattern 28, the transparent conductive film 7 and the second metal film 8 are formed. To be specific, the transparent conductive film 7 is formed over the entire insulating substrate 1 so as to cover the raise/recess pattern 27 and the insulating pattern 28. Further, the second metal film 8 is formed on the film 7 and over the entire insulating substrate 1. As in embodiment 3, for example, an ITO film of a mixture of indium oxide (In₂O₃) and tin oxide (SnO₂) can be used as the transparent conductive film 7. Here, the ITO film of 100 nm in thickness is formed by the sputtering method using Ar gas, and a Cr film of 200 nm in thickness is formed as the second metal film 8 by the DC magnetron sputtering method using Ar gas. By this means, the configuration shown in FIG. 18E is obtained.

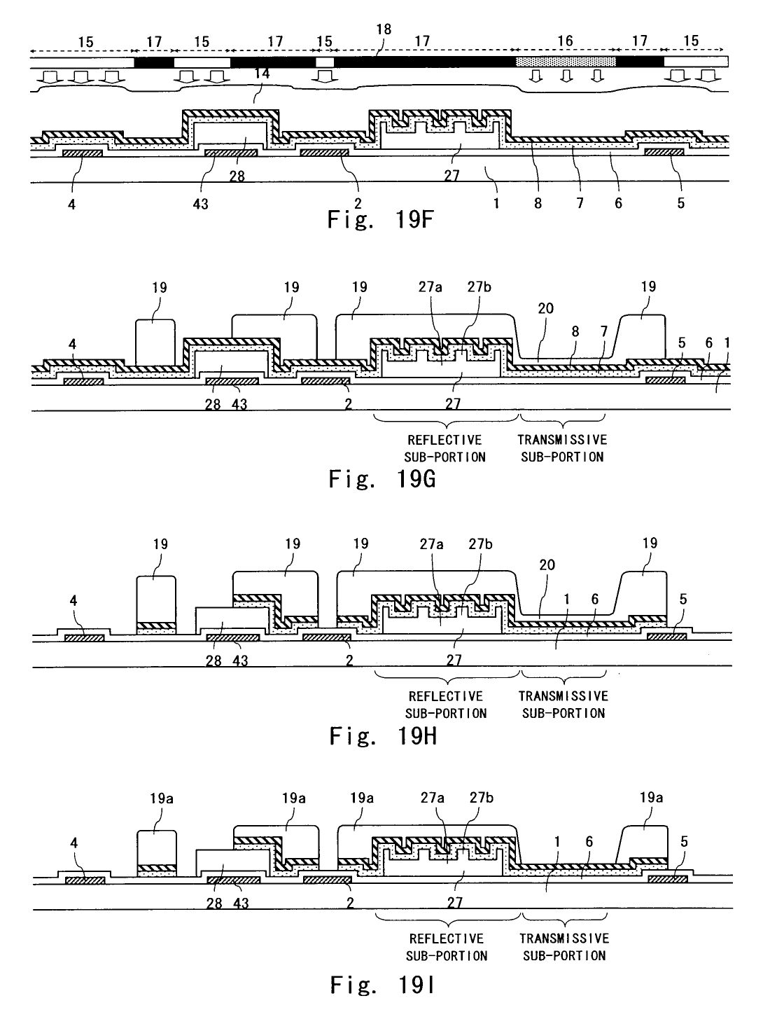

Thereafter, as in embodiment 3, a photolithography process is performed to pattern the transparent conductive film 7 and the second metal film 8 (ST307). Because ST307 and the subsequent steps are the same as in embodiment 3, detailed description thereof is omitted. Note that since, as mentioned above, the photolithography process for forming the raise/recess pattern 27 and the insulating pattern 28 is a second one of the present embodiment, the photolithography process of ST307 is a third one. The photoresist 14 is coated on the second metal film 8, and the multiphase exposure is performed using the photomask 18 as shown in FIG. 19F. Then, the photoresist 14 is developed and postbaked, and thereby resist patterns 19 and 20 different in thickness are formed simultaneously as shown in FIG. 19G. The thicker resist pattern 19 is formed on the regions where the drain electrode 9 and the source electrode 11, the source terminal 13, the source line 44, and the reflective pixel electrode 10b are to be provided, and the thinner resist pattern 20 is formed on the region which is to be the transmissive sub-portion of the pixel electrode portion where the reflective pixel electrode 10b is not provided.

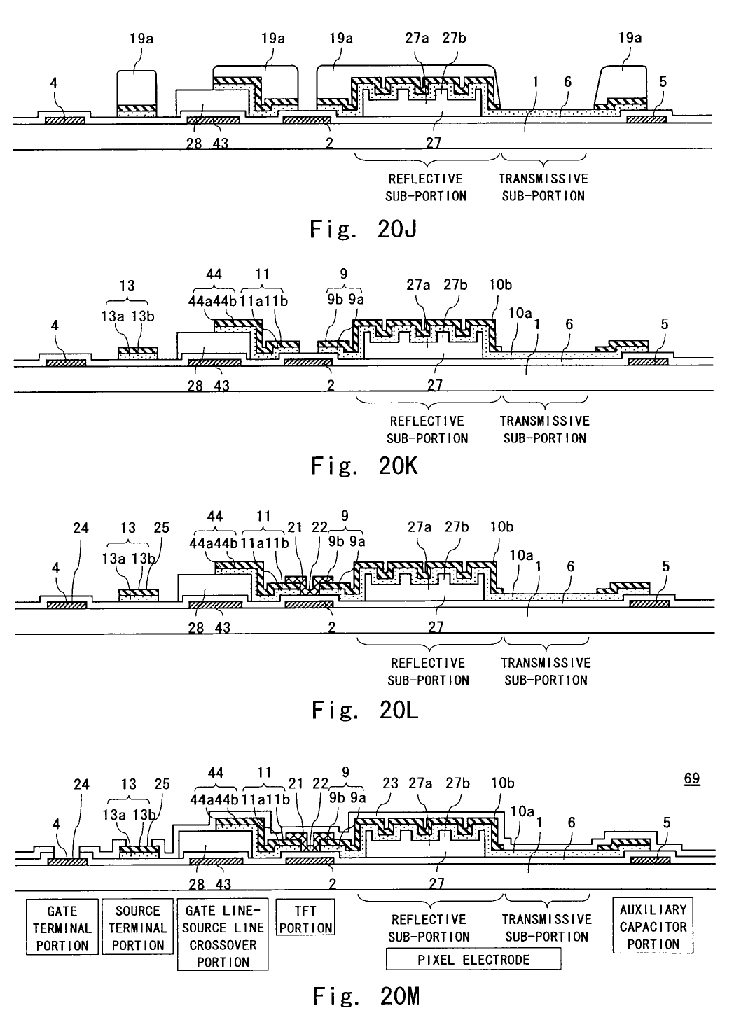

Next, in FIG. 19H, the first wet etching of the second metal film 8 (ST308) and the wet etching of the transparent conductive film 7 (ST309) are performed with these masking resist patterns 19, 20. Thereafter, ashing is performed (ST310), thereby removing the thinner resist pattern 20 as shown in FIG. 19I. At this time, the thicker resist pattern 19 is thinned into a resist pattern 19a. Then, the second metal film 8 is wet etched for the second time with the masking resist pattern 19a (ST311). At this time, since covered by the resist pattern 19a, the second metal film 8 on the raise/recess pattern 27 is not etched but left. By this means, as shown in FIG. 20J, the transparent conductive film 7 is exposed at only the transmissive sub-portion of the pixel electrode portion. Then, the resist pattern 19a is removed by stripping off, and the whole is cleaned with pure water (ST312). In this way, the drain electrodes 9a, 9b, the transmissive pixel electrode 10a, the reflective pixel electrode 10b, the source electrodes 11a, 11b, the source terminals 13a, 13b, and the source lines 44a, 44b are formed as shown in FIG. 20K.

The semiconductor film is formed over these (ST313). Then, through a photolithography process (ST314), etching (ST315), and resist stripping-off and pure-water cleaning (ST316), the semiconductor film 21 having the channel region 22 is formed as shown in FIG. 20L (ST316). Note that since, as mentioned above, the photolithography process for forming the raise/recess pattern 27 and the insulating pattern 28 is a second one of the present embodiment, the photolithography process of ST314 is a fourth one.

The second insulating film as the passivation film 23 is formed on the semiconductor film (ST317). Then, through a photolithography process (ST318), etching (ST319), and resist stripping-off and pure-water cleaning (ST320), the source terminal opening 25 and the gate terminal opening 24 are formed. Note that since, as mentioned above, the photolithography process for forming the raise/recess pattern 27 and the insulating pattern 28 is a second one of the present embodiment, the photolithography process of ST318 is a fifth one. Through the above steps, a TFT array substrate 69 shown in FIG. 20M is completed.

In the present embodiment, the raise/recess pattern 27 having raises/recesses is formed under the reflective pixel electrode 10b in this way, so that the reflective pixel electrode 10b has raises and recesses. Thus, external light can be effectively scattered, thereby improving the display characteristic of the reflective sub-portion. Further, the optical path lengths of reflected display light and of transmitted display light can be adjusted by controlling the film thickness of the raise/recess pattern 27 provided on the reflective sub-portion, thus improving display characteristics. Yet further, in the present embodiment the insulating pattern 28 is formed in the gate line-source line crossover portion. Thus, the source line 44 crosses over the gate line 43, with the gate insulating film 6 and the insulating pattern 28 interposed therebetween. Hence, a short-circuit failure between the gate line 43 and the source line 44 can be prevented.

Further, with realizing the five-mask process, the formation of the channel region 22 is performed with use of a photolithography process separate from the formation of the drain electrode 9 and the source electrode 11. When patterning the semiconductor film to form the channel region, multiphase exposure such as halftone or gray tone is not used. Because no thinner portion of the resist pattern is formed over the region between the drain electrode 9 and the source electrode 11, the distance between the drain electrode 9 and the source electrode 11 can be easily controlled. Therefore, as in embodiments 1 to 6, the control of the channel length is easier, and thus variation in channel length can be suppressed.

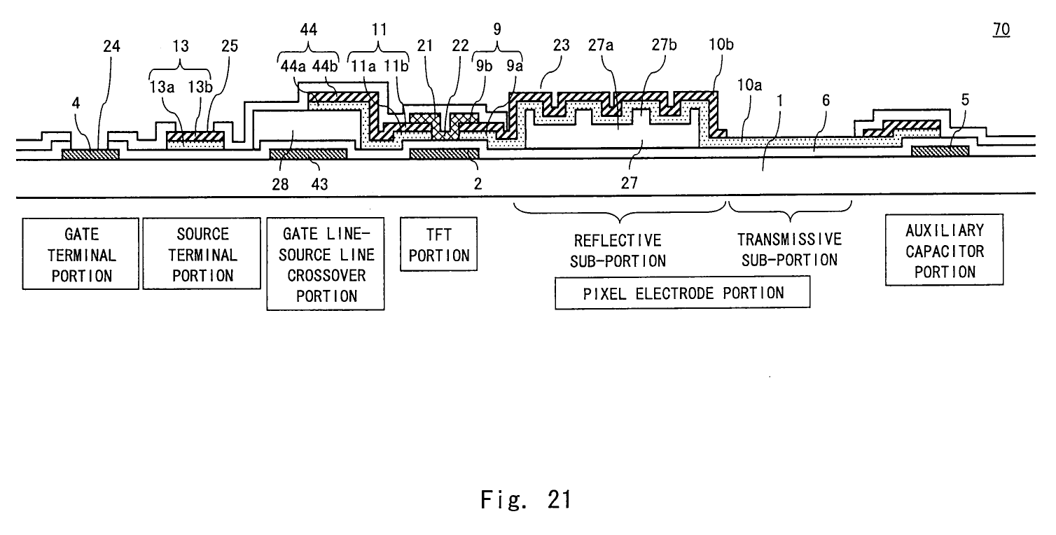

Also in the present embodiment, as in embodiment 3, part of the passivation film 23 that is on the pixel electrode portion can be removed. FIG. 21 shows a cross-sectional structure of a TFT array substrate 70 according to another example of the present embodiment 7. As shown in FIG. 21, the passivation film 23 is not formed on the pixel electrode portion so that part of the transmissive pixel electrode 10a and the reflective pixel electrode 10b are exposed. By this means, optical transmittance is improved, thus improving display brightness. Moreover, although in the present embodiment the case where the raise/recess pattern 27 is provided on the TFT array substrate 63 of embodiment 3 has been described illustratively, it may be provided on the TFT array substrate 65 or 66 of embodiment 4. The present embodiment can be used in combination with embodiments 5, 6 as needed.

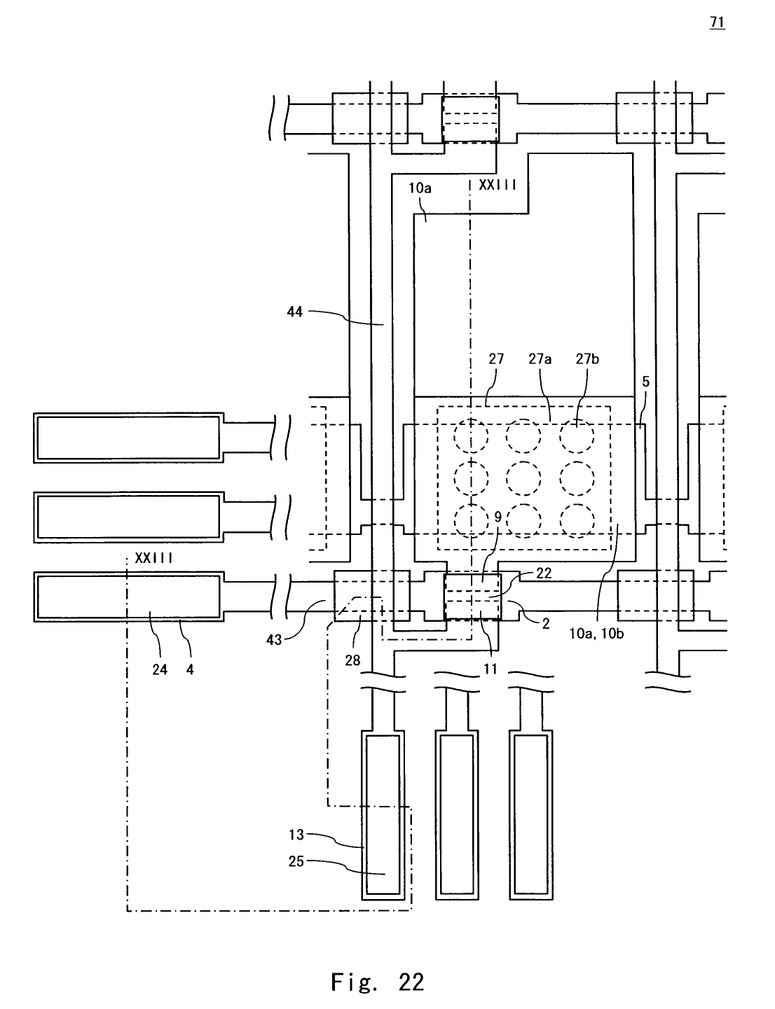

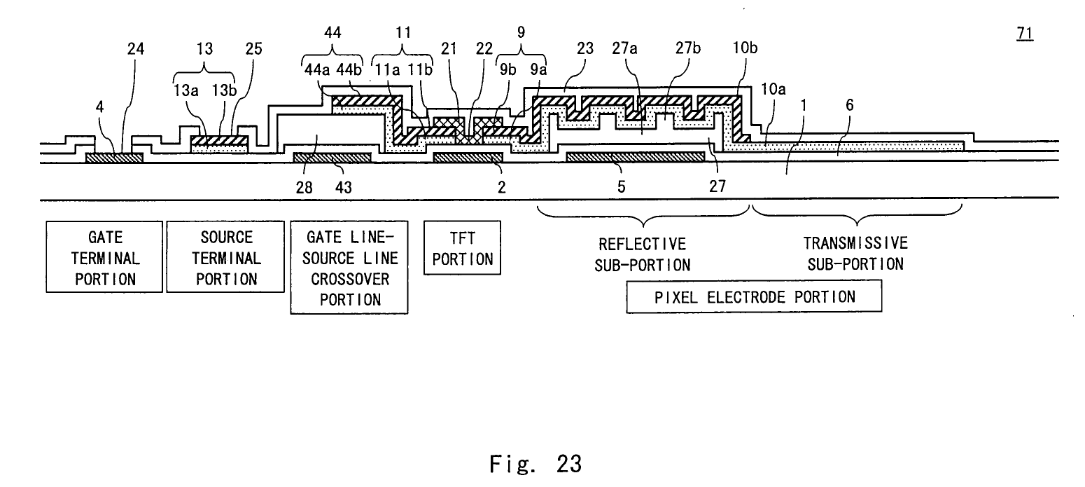

Furthermore, in the present embodiment, the auxiliary capacitor may be provided in the reflective sub-portion of the pixel electrode portion. FIG. 22 is a plan view of a TFT array substrate 71 according to yet another example of the present embodiment 7, and FIG. 23 is a sectional view on line XXIII-XXIII of FIG. 22. In FIGS. 22, 23, the auxiliary capacitor electrode 5 is formed under the reflective pixel electrode 10b. This configuration improves the aperture ratio of the pixel, thus enabling higher performance in display characteristics and lower power consumption. Hence, not being limited to the present embodiment, in transflective and reflective liquid crystal displays, the auxiliary capacitor is preferably provided in the reflective portion of the pixel electrode portion.

Although in the present embodiment the case where the raise/recess pattern 27 is provided in only the reflective sub-portion has been described illustratively, the raise/recess pattern 27 can be formed in the transmissive sub-portion as long as a transparent material having high transparency is used for the raise/recess pattern 27. By this means, the size of the step between the reflective sub-portion and the transmissive sub-portion can be finely adjusted. For example, the raise/recess pattern 27 may extend to cover the transmissive sub-portion, or a pattern thinner in film thickness than the raise/recess pattern 27 of the reflective sub-portion may be formed extending over the transmissive sub-portion. This pattern may be the same in film thickness as, e.g., the recess 27a.

In the above embodiments 1 to 7, various active matrix liquid crystal displays having a TFT array substrate have been described, but this invention is not limited to this. This invention can be applied to display devices using a display material such as organic EL or an electronic paper, other than liquid crystal. The case where an ITO film is formed as the transparent conductive film 7 has been described illustratively, but this invention is not limited to this. For example, an amorphous ITO film or an IZO film of a mixture of indium oxide and zinc oxide can be used. Or, an ITZO film of a mixture of indium oxide, tin oxide, and zinc oxide may be formed as the transparent conductive film 7. The amorphous ITO film, the IZO film, and the ITZO film can be etched with oxalic acid that is weak acid. Therefore, in the etching of the transparent conductive film 7, the other lines and electrodes are not eroded, hence further improving yield.

The above explanation is to describe the embodiments of the present invention and the present invention is not limited to the above embodiments. Moreover, those skilled in the art can change, add and change each component of the above embodiments easily in the scope of the present invention.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A thin film transistor array substrate comprising:
a gate electrode formed on a substrate;
a gate insulating film formed over the gate electrode;
a source electrode and a drain electrode that are formed on the gate insulating film, the source electrode and the drain electrode including a transparent conductive film and a metal film formed on the transparent conductive film;
a semiconductor film formed over the source electrode and the drain electrode to be electrically connected to the source electrode and the drain electrode; and
a pixel electrode formed extending from the drain electrode.

2. The thin film transistor array substrate according to claim 1, wherein the pixel electrode includes a transparent conductive film extending from the transparent conductive film included in the drain electrode.

3. The thin film transistor array substrate according to claim 2, wherein the pixel electrode includes a metal film extending from the metal film included in the drain electrode.

4. The thin film transistor array substrate according to claim 3, wherein the pixel electrode has a region where the metal film is not formed.

5. The thin film transistor array substrate according to claim 3, further comprising:
a raise/recess pattern having raises/recesses formed between the gate insulating film and the transparent conductive film so as to be covered by the metal film of the pixel electrode.

6. The thin film transistor array substrate according to claim 5, wherein the raise/recess pattern is formed by an organic film.

7. The thin film transistor array substrate according to claim 1, further comprising:
an ohmic contact film formed between the semiconductor film and the source electrode and between the semiconductor and the drain electrode respectively,
wherein the semiconductor film is electrically connected to the source electrode and the drain electrode via the ohmic contact film.

8. The thin film transistor array substrate according to claim 7, wherein the ohmic contact film is a film of conductive metal oxide made by adding oxygen atoms to Al, Cr, or Ti.

9. The thin film transistor array substrate according to claim 7, wherein the ohmic contact film is made of conductive metal nitride.

10. The thin film transistor array substrate according to claim 1, wherein the underside of the semiconductor film is in contact with the metal film included in the source electrode and the drain electrode.

11. The thin film transistor array substrate according to claim 1, wherein the underside of the semiconductor film is in contact with the transparent conductive film included in the source electrode and the drain electrode.

12. A display device comprising the thin film transistor array substrate according to claim 1.

13. A manufacturing method for a thin film transistor array substrate comprising the steps of:
forming a gate electrode on a substrate;
forming a gate insulating film to cover the gate electrode;
forming a transparent conductive film on the gate insulating film;
forming a metal film on the transparent conductive film;
forming a resist pattern having difference in film thickness on the metal film by means of multi-tone exposure;
forming a source electrode and a drain electrode by etching the transparent conductive film and the metal film with the resist pattern having difference in film thickness as a mask;
removing a thinner portion of the resist pattern by ashing the resist pattern having difference in film thickness;
forming a pixel electrode by etching the metal film with the resist pattern left after the removal of the thinner portion as a mask; and
forming a semiconductor film over the source electrode and the drain electrode after forming the pixel electrode and removing the resist pattern left.

14. The manufacturing method for the thin film transistor array substrate according to claim 13, further comprising the step of:
forming a raise/recess pattern on at least part of a region which is to be the pixel electrode after the formation of the gate insulating film and before the formation of the transparent conductive film,
wherein in the step of forming the pixel electrode, the etching is performed such that the metal film over the raise/recess pattern is left.

15. The manufacturing method for the thin film transistor array substrate according to claim 14, wherein in the step of forming the raise/recess pattern, a photosensitive resin film is formed on the gate insulating film, and the raise/recess pattern having difference in film thickness is formed by means of multi-tone exposure.

16. The manufacturing method for the thin film transistor array substrate according to claim 15, wherein the photosensitive resin film is a resist or an acrylic-based organic resin film.

17. The manufacturing method for the thin film transistor array substrate according to claim 13, further comprising the step of:
forming an ohmic contact film on the metal film,
wherein in the step of forming the source electrode and the drain electrode, the ohmic contact film is etched,
in the step of forming the pixel electrode, the ohmic contact film is etched, and
in the step of forming the semiconductor film, the semiconductor film is formed to be in contact with the ohmic contact film.

18. The manufacturing method for the thin film transistor array substrate according to claim 17, wherein the ohmic contact film is a film of conductive metal oxide made by adding oxygen atoms to Al, Cr, or Ti, or a film of conductive metal nitride.

19. The manufacturing method for the thin film transistor array substrate according to claim 13, wherein in the step of forming the semiconductor film, the semiconductor film is formed to be in contact with the metal films included in the source electrode and the drain electrode.

20. The manufacturing method for the thin film transistor array substrate according to claim 13, wherein in the step of etching the metal film with the resist pattern left after the removal of the thinner portion as a mask, the metal films of the source electrode and the drain electrode are removed by the etching, and
in the step of forming the semiconductor film, the semiconductor film is formed to be in contact with the transparent conductive films included in the source electrode and the drain electrode.
